(19) United States
(12) Patent Application Publication
(10) Pub. No.: US 2026/0092395 A1
(43) Pub. Date: Apr. 2, 2026

(54) Treatment of Graphite Structures for Use Crystal Growth System or Deposition System for Growing Silicon Carbide

(71) Applicant: Wolfspeed, Inc., Durham, NC (US)

(72) Inventors: Simon Bubel, Carrboro, NC (US); Alexander Kevin Shveyd, Chapel Hill, NC (US)

(21) Appl. No.: 18/963,130

(22) Filed: Nov. 27, 2024

Related U.S. Application Data
(60) Provisional application No. 63/700,630, filed on Sep. 28, 2024.

(51) Int. Cl. C30B 23/00; C01B 32/225; C30B 29/36

(52) U.S. Cl. CPC C30B 23/005; C01B 32/225; C30B 29/36

(57) ABSTRACT

Systems and methods for treatment of graphite structure for use in, for instance, crystal growth systems or deposition systems are provided. In one example, the method includes implementing a treatment process to a graphite structure to alter one or more characteristics of the graphite structure to produce a treated graphite structure. The method includes providing the treated graphite structure to a crystal growth system or a deposition system. At least a portion of the treated graphite structure has an exposed graphite surface within the crystal growth system or the deposition system.

### PRIORITY CLAIM

The present application claims the benefit of priority of U.S. Provisional Application Ser. No. 63/700,630, filed on Sep. 28, 2024, which is incorporated herein by reference for all purposes.

### FIELD

The present disclosure relates generally to systems and methods for treating graphite structures for use in crystal growth systems or deposition systems, such as silicon carbide crystal growth systems for growing crystalline silicon carbide semiconductor workpieces for fabrication of semiconductor devices.

### BACKGROUND

Semiconductor devices, including power semiconductor devices based on wide bandgap materials, may be formed on a semiconductor wafer as part of a semiconductor fabrication process. Single crystal silicon carbide (SiC) has proven to be a very useful wafer material in the manufacture of such semiconductor devices. Due to its physical strength and excellent resistance to many chemicals, silicon carbide may be used to fabricate very robust substrates adapted for use in the semiconductor industry. Silicon carbide has excellent electrical properties, including radiation hardness, high breakdown field, a relatively wide band gap, high saturated electron drift velocity, high-temperature operation, and absorption and emission of high-energy photons in the blue, violet, and ultraviolet regions of the optical spectrum.

### SUMMARY

Aspects and advantages of embodiments of the present disclosure will be set forth in part in the following description, or can be learned from the description, or can be learned through practice of the embodiments.

In an aspect, the present disclosure provides an example method for treating a graphite structure. The method includes implementing a treatment process to a graphite structure to alter one or more characteristics of the graphite structure to produce a treated graphite structure. The method includes providing the treated graphite structure to a crystal growth system or a deposition system. At least a portion of the treated graphite structure has an exposed graphite surface within the crystal growth system or the deposition system.

In an aspect, the present disclosure provides an example method for treating a graphite structure. The method includes implementing a treatment process to a graphite structure to alter one or more permeability characteristics of the graphite structure to produce a treated graphite structure. The method includes providing the treated graphite structure to a crystal growth system or a deposition system. One or more permeability characteristics are associated with a flow of a fluid through the treated graphite structure.

In an aspect, the present disclosure provides an example crystal growth system. The crystal growth system includes a crucible. The crystal growth system includes a seed holder. The crystal growth system includes a source material within the crucible. The crystal growth system includes a treated graphite structure. The treated graphite structure accommodates a flow of a fluid through the treated graphite structure. The treated graphite structure has an exposed graphite surface in the crucible.

In an aspect, the present disclosure provides an example system. The system includes a workpiece holder operable to hold a graphite structure for a crystal growth system. The system includes a treatment platform. The system includes a controller configured to control the treatment platform to implement a treatment process on the graphite structure to alter one or more characteristics of the graphite structure to produce a treated graphite structure.

These and other features, aspects and advantages of various embodiments will become better understood with reference to the following description and appended claims. The accompanying drawings, which are incorporated in and constitute a part of this specification, illustrate embodiments of the present disclosure and, together with the description, serve to explain the related principles.

### BRIEF DESCRIPTION OF THE DRAWINGS

Detailed discussion of embodiments directed to one of ordinary skill in the art are set forth in the specification, which makes reference to the appended figures, in which:

FIG. 1 depicts a sublimation system having a treated graphite structure according to example embodiments of the present disclosure;

FIG. 2 depicts a sublimation system having a treated graphite structure according to example embodiments of the present disclosure;

FIG. 3 depicts a sublimation system having a treated graphite structure according to example embodiments of the present disclosure;

FIG. 4 depicts permeability characteristics associated with an untreated graphite structure according to example embodiments of the present disclosure;

FIG. 5 depicts an overview of an example method for treating a graphite structure according to example embodiments of the present disclosure;

FIG. 6 depicts permeability characteristics associated with a treated graphite structure according to example embodiments of the present disclosure;

FIG. 7 depicts an overview of an example method according to example embodiments of the present disclosure;

FIG. 8 depicts an overview of an example method according to example embodiments of the present disclosure;

FIG. 9 depicts an overview of an example method according to example embodiments of the present disclosure;

FIG. 10 depicts an example electrochemical treatment platform according to examples of the present disclosure;

FIG. 11 depicts an example plasma-based treatment platform according to examples of the present disclosure.

FIG. 12 depicts an example laser-based treatment platform according to examples of the present disclosure.

FIG. 13 depicts a flow chart diagram of an example method according to example embodiments of the present disclosure.

FIG. 14A and FIG. 14B depict a perspective view of a graphite source retention mechanism according to example embodiments of the present disclosure;

FIG. 15 depicts a deposition system having a treated graphite structure according to example embodiments of the present disclosure;

FIGS. 16A-23 depict example crystal growth systems according to example embodiments of the present disclosure.

Repeat use of reference characters in the present specification and drawings is intended to represent the same and/or analogous features or elements of the present invention.

### DETAILED DESCRIPTION

Reference now will be made in detail to embodiments, one or more examples of which are illustrated in the drawings. Each example is provided by way of explanation of the embodiments, not limitation of the present disclosure. In fact, it will be apparent to those skilled in the art that various modifications and variations may be made to the embodiments without departing from the scope or spirit of the present disclosure. For instance, features illustrated or described as part of one embodiment may be used with another embodiment to yield a still further embodiment. Thus, it is intended that aspects of the present disclosure cover such modifications and variations.

Aspects of the present disclosure are directed to systems and methods for treating graphite structures used in crystal growth systems and deposition systems (e.g., epitaxial reactor), such as silicon carbide crystal growth systems. Silicon carbide crystalline material may be produced using various seeded sublimation crystal growth processes. In some silicon carbide crystal growth processes, a seed material and a source material are arranged in a reaction crucible which is then heated to a sublimation temperature of the source material. By controlled heating of the environment surrounding the reaction crucible, a thermal gradient is developed between the sublimating source material and the marginally cooler seed material. By means of the thermal gradient, source material in a vapor phase is transported onto the seed material where it is deposited to grow a solid bulk crystalline boule. This type of sublimation crystal growth process is commonly referred to as a physical vapor transport (PVT) process.

Graphite structures may be used in crystal growth systems and deposition systems (e.g., epitaxial reactors), such as silicon carbide crystal growth sublimation systems. For instance, the graphite structure may be a crucible used in the PVT system. For instance, in some examples, graphite structures may accommodate a flow of a fluid (e.g., vapor or gas) during sublimation of a source material.

Characteristics of graphite structures within a crystal growth system may influence crystal growth process parameters (e.g., PVT crystal growth process parameters) through thermodynamic and kinetic factors. As such, graphite structures in crystal growth systems may need to have strictly controlled properties, including, for example, morphology, density, porosity, pore size distribution, gas permeability, flexural strength, resistivity, thermal conductivity (TC), emissivity, coefficient of thermal expansion (CTE), purity, and/or particle erosion rate, etc. Of these example characteristics, permeability characteristics such as, by non-limiting example, porosity, pore size, pore distribution, gas permeability, and/or particle erosion rate of a graphite structure may influence crystal growth conditions. As an example, particle erosion from a graphite structure during a crystal growth process may lead to carbon contaminants in the crystalline material, providing for defect formation in the crystalline material and/or other anomalies during a crystal growth process.

In some instances, available graphite structures for use in crystal growth systems do not meet strictly controlled specification requirements of the crystal growth process. Indeed, in some cases, only a portion of an available graphite structure received, for instance, from a supplier, may meet the required specifications. As a result, the entire graphite structure may be unsuitable for use with crystal growth processes and must be discarded, leading to increased material waste and increased costs. As such, the ability to tailor the properties and characteristics of graphite structures to a particular crystal growth process, such as a PVT crystal growth process, would be useful.

Certain methods to tailor the properties and characteristics of graphite structures may include, for instance, graphite-based manufacturing and refinement techniques such as annealing or washing. Other methods may include providing a pyrolytic carbon coating or providing a tantalum carbide coating to graphite structures. Certain methods may include, for instance, changing the crystal growth process (e.g., PVT crystal growth process), including changing the design of the crystal growth system or changing the crystal growth process parameters (e.g., PVT crystal growth process parameters), to accommodate wider specifications for the properties of available graphite structures. However, despite these methods, many graphite structures still may not meet the strictly controlled specifications required for certain crystal growth processes, such as PVT crystal growth processes.

Accordingly, aspects of the present disclosure are directed to implementing a treatment process on graphite structures to modify one or more characteristics of the graphite structures to produce treated graphite structures. The treated graphite structures may be, for instance, a component part of a crystal growth system, such as a crucible, a seed holder or a workpiece holder, a source cap or other structure used in the crystal growth system or other component parts of the crystal growth system (e.g., a susceptor, a crucible, a seed holder, etc.).

The treatment process may render a previously unsuitable graphite structure to be suitable for use in a crystal growth process. In some examples, the treatment process may include a mechanical, a physical, or a chemical treatment process.

In some examples, the treatment process may be a selective treatment process that may modify one or more characteristics of the graphite structure at specific locations or depths (e.g., modifying one or more characteristics at the surface of the graphite structures, modifying one or more characteristics to a specific depth within the graphite structure, etc.) such that one or more characteristics of a first portion of the graphite structure are modified and one or more characteristics of a second portion of the graphite structure remain unmodified. In some examples, the treatment process may leave a portion of the graphite structure exposed. In some examples, the treatment process may be implemented as a pretreatment process on the graphite structure, such as a pretreatment process of the graphite structure prior to application of a coating (e.g., a pyrolytic carbon coating or tantalum carbide coating). In some examples, the treatment process may be a post-treatment process performed after application of a coating (e.g., a pyrolytic carbon coating or tantalum carbide coating). Example coatings that may be used are disclosed in U.S. Provisional Application Serial Nos. 63/700,682, filed on Sep. 28, 2024, 63/700,685, filed on Sep. 28, 2024 and 63/700,686, filed on Sep. 28, 2024, which are incorporated herein by reference.

For instance, in some examples, the treatment process may be a pressure shock wave treatment process. In some examples, the pressure shock wave treatment process may be a homogenization process. In some examples, the pressure shock wave treatment process may be a laser-based cavitation process. In some examples, the pressure shock wave treatment process may be an ultrasonic cavitation process.

In some examples, the treatment process may be a stimulation of vibrational modes in the graphite structure. In some examples, the stimulation of vibrational modes may be applying mechanical interactions to a crystal lattice of the graphite structures. In some examples, the stimulation of vibrational modes may include providing the graphite structure in a fluid and transferring vibrational energy to the graphite structures through the fluid. In some examples, the stimulation of vibrational modes may include providing the graphite structures to a solid interface that imparts vibrational motion. In some examples, the stimulation of vibrational modes may include transferring vibrational energy to the graphite structures with electrical or electromagnetic radiation. In some examples, the stimulation of vibrational modes may include modifying a lattice of the graphite structures to form hybrid atomic orbitals.

In some examples, the treatment process may be a laser-based process performed on the graphite structures. For instance, one or more lasers may be emitted onto the graphite structures to remove material from the graphite structures (e.g., through an ablation process) or to heat the graphite structures.

In some examples, the treatment process may be a chemical exfoliation process. In some examples, the chemical exfoliation process may expose the graphite structures to a gas that reacts with the graphite structure. In some examples, the chemical exfoliation process may expose the graphite structures to a basic solution. In some examples, the basic solution may comprise potassium hydroxide, sodium hydroxide, or ammonium hydroxide.

In some examples, the treatment process may expose the graphite structures to an electrochemical bath. In some examples, the treatment process may expose the graphite structures to a plasma, such as an oxidizing plasma. In some examples, the treatment process may include providing the graphite structures in a liquid and causing evaporation of the liquid.

In some examples, the treatment process may be a thermal treatment of the graphite structures. In some examples, the thermal treatment process may include heating the graphite structures to a temperature in a range of about 50° C. to about 130° C. to polymerize infiltrated or adsorbed materials. In some examples, the thermal treatment process may include heating the graphite structures to a temperature in a range of about 25° C. to about 80° C. to conduct dry-cleaning processes. In some examples, the thermal treatment process may include heating the graphite structures to a temperature in a range of about 60° C. to about 180° C. to rapidly evaporate solvents, such as organic solvents, water, or alcohols. In some examples, the thermal treatment process may include heating the graphite structures to a temperature in a range of about 100° C. to about 300° C. to evaporate higher molecular weight organics. In some examples, the thermal treatment process may include heating the graphite structures to a temperature in a range of about 300° C. to about 2000° C. to oxidize, desorb chemisorbed matter, or sinter the graphite structure. In some examples, the thermal treatment process may include heating the graphite structures to a temperature in a range of about 2000° C. to about 3000° C. to recrystallize the graphite structures.

Aspects of the present disclosure are discussed with conducting a treatment process with no subsequent coating such that the graphite structure has an exposed graphite surface. In some examples, the treatment processes disclosed herein may be used in combination with a coating. The coating may impart additional benefits to the exposed graphite surface of the treated graphite structures, such as, by non-limiting example, an increased melting point, enhanced chemical stability, alterations to density, and so forth. The coating may impart additional beneficial properties to the treated graphite structure without altering the underlying material characteristics and properties (i.e., the coating may impart additional resistance to processing conditions without altering the characteristics or properties of the underlying treated graphite structure). This coating can include, for instance, a pyrolytic carbon coating or tantalum carbide (TaC). In some examples, the treatment process may be implemented as a pretreatment process on the graphite structure, such as a pretreatment process of the graphite structure prior to application of a coating. In some examples, the treatment process may be a post-treatment process performed after application of a coating.

Aspects of the present disclosure provide numerous technical effects and benefits. For instance, performing a treatment process that alters the characteristics (e.g., permeability characteristics) of graphite structures, such as a crucible, a seed holder, a source cap, or other structure in a crystal growth system, may allow for a wider variety of carbon-based inputs to be employed in a multitude of industrial applications and/or manufacturing techniques, such as in crystal growth processes. A wider variety of graphite-based inputs may improve process scaling capabilities and/or improve sourcing avenues for such materials. Further, a treatment process that may modify graphite structures that are out of specification to make them suitable for use in a crystal growth process may lead to reduced need to discard graphite structures that do not meet specifications, lowering material waste and costs. In addition, performing a treatment process that alters the properties and characteristics of graphite structures in a crystal growth system may reduce particle erosion of the graphite structures, leading to improved growth conditions and reduced defect and/or anomaly formation in the crystal growth process.

It will be understood that, although the terms first, second, third, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” “comprising,” “includes” and/or “including” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms used herein should be interpreted as having a meaning that is consistent with their meaning in the context of this specification and the relevant art and will not be interpreted in an idealized or overly formal sense unless expressly so defined herein.

It will be understood that when an element such as a layer, region, or substrate is referred to as being “on” or extending “onto” another element, it may be directly on or extend directly onto the other element or intervening elements may also be present. In contrast, when an element is referred to as being “directly on” or extending “directly onto” another element, there are no intervening elements present, except in some examples an attach material (e.g., die-attach material, solder, paste, adhesive, sintered material or other material may be present. It will also be understood that when an element is referred to as being “connected” or “coupled” to another element, it may be directly connected or coupled to the other element or intervening elements may be present. In contrast, when an element is referred to as being “directly connected” or “directly coupled” to another element, there are no intervening elements present, except in some examples an attach material (e.g., die-attach material, solder, paste, adhesive, sintered material or other material may be present.

Relative terms such as “below” or “above” or “upper” or “lower” or “horizontal” or “lateral” or “vertical” may be used herein to describe a relationship of one element, layer or region to another element, layer or region as illustrated in the figures. It will be understood that these terms are intended to encompass different orientations of the device in addition to the orientation depicted in the figures.

Embodiments of the disclosure are described herein with reference to cross-section illustrations that are schematic illustrations of idealized embodiments of the disclosure. The thickness of layers and regions in the drawings may be exaggerated for clarity. Additionally, variations from the shapes of the illustrations as a result, for example, of manufacturing techniques and/or tolerances, are to be expected. Thus, embodiments of the disclosure should not be construed as limited to the particular shapes of regions illustrated herein but are to include deviations in shapes that result, for example, from manufacturing. Similarly, it will be understood that variations in the dimensions are to be expected based on standard deviations in manufacturing procedures. As used herein, “approximately” or “about” includes values within 10% of the nominal value.

Like numbers refer to like elements throughout. Thus, the same or similar numbers may be described with reference to other drawings even if they are neither mentioned nor described in the corresponding drawing. Also, elements that are not denoted by reference numbers may be described with reference to other drawings.

Some embodiments of the invention are described with reference to semiconductor layers and/or regions which are characterized as having a conductivity type such as n type or p type, which refers to the majority carrier concentration in the layer and/or region. Thus, N type material has a majority equilibrium concentration of negatively charged electrons, while P type material has a majority equilibrium concentration of positively charged holes. Some material may be designated with a “+” or “−” (as in N+, N−, P+, P−, N++, N−−, P++, P−−, or the like), to indicate a relatively larger (“+”) or smaller (“−”) concentration of majority carriers compared to another layer or region. However, such notation does not imply the existence of a particular concentration of majority or minority carriers in a layer or region.

In the drawings and specification, there have been disclosed typical embodiments and, although specific terms are employed, they are used in a generic and descriptive sense only and not for purposes of limitation of the scope set forth in the following claims.

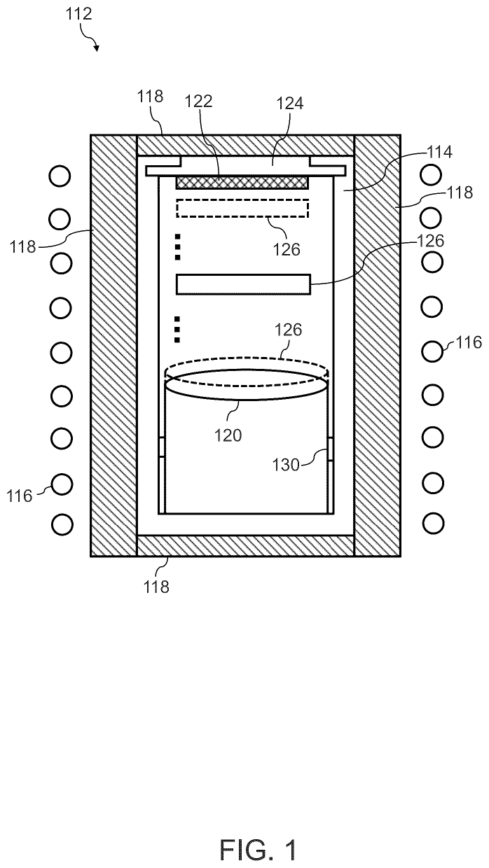

FIG. 1 is a cross-sectional schematic diagram of a crystal growth system 112 adapted for use in a crystal growth process of the type contemplated by certain embodiments of the disclosure. The crystal growth system 112 includes a reaction crucible 114 (also referred to as a susceptor or growth cell) and a plurality of induction coils 116 adapted to heat the reaction crucible 114 when electrical current is applied. Alternatively, a resistive heating approach may be applied to the heating of the reaction crucible 114. Using any competent heating mechanism and approach, the temperature within the crystal growth system 112 may be controllable. The reaction crucible 114 may be, at least in part, a graphite structure.

The crystal growth system 112 may also include one or more gas inlet and gas outlet ports and associated equipment allowing the controlled introduction and evacuation of gas from an environment surrounding the reaction crucible 114. The introduction and evacuation of various gasses to or from the environment surrounding the reaction crucible 114 may be accomplished using a variety of inlets/outlets, pipes, valves, pumps, gas sources, and controllers. It will be further understood by those skilled in the art, using the disclosures provided herein, that the crystal growth system 112 may further incorporate in certain embodiments a water-cooled quartz vessel.

The reaction crucible 114 may be surrounded by an insulation material 118. The composition, size, and placement of the insulation material 118 will vary with an individual crystal growth system, such as the crystal growth system 112 of FIG. 1, to define and/or maintain desired thermal gradients (both axially and radially) in relation to the reaction crucible 114. For purposes of clarity, the term, “thermal gradient,” will be used herein to describe one or more thermal gradient(s) associated with the reaction crucible 114. Those skilled in the art, using the disclosures provided herein, recognize that “the thermal gradient” established in embodiments of the disclosure will contain (or may be further characterized as having) axial and radial gradients, or may be characterized by a plurality of isotherms.

Prior to establishment of the thermal gradient, the reaction crucible 114 is loaded with a source material 120. As such, the reaction crucible 114 includes one or more portions, at least one of which is capable of providing the source material 120. The source material 120 may be held in a lower portion of the reaction crucible 114, as is common for one type of crystal growth system, such as the crystal growth system 112 of FIG. 1.

Example silicon carbide source materials are disclosed in U.S. Provisional Application Ser. Nos. 63/689,294, filed on Aug. 30, 2024 and in 63/689,291, filed on Aug. 30, 2024, both of which are incorporated herein by reference.

A seed material 122 may be placed above or in an upper portion of the reaction crucible 114. The seed material 122 may take the form of a mono-crystalline silicon carbide seed wafer having a diameter from about 50 mm to about 310 mm. A silicon carbide crystal boule will be grown from the seed material 122 during a crystal growth process.

In the embodiment illustrated in FIG. 1, a seed holder 124 is used to hold the seed material 122. The seed holder 124 is securely attached to the reaction crucible 114 in an appropriate fashion. For example, in the orientation illustrated in FIG. 1, the seed holder 124 is attached to an uppermost portion of the reaction crucible 114 to hold the seed material 122 in a desired position. In some embodiments, the seed holder 124 is fabricated from carbon (e.g., graphite). The attachment of the seed material 122 (e.g., a seed wafer) to the seed holder 124 within the crystal growth system 112 may be made, for instance, by a uniform thermal contact. Various techniques may be used to implement a uniform thermal contact. For example, the seed material 122 may be placed in direct physical contact with the seed holder 124, or an adhesive may be used to fix the seed material 122 to the seed holder 124, so as to provide uniform conductive and/or radiative heat transfer over substantially the entire area between the seed material 122 and the seed holder 124.

In the embodiment illustrated in FIG. 1, the seed holder 124 is used to hold the seed material 122. The seed holder 124 is securely attached to reaction crucible 114 in an appropriate fashion using conventional techniques. For example, in the orientation illustrated in FIG. 1, the seed holder 124 is attached to an uppermost portion of the reaction crucible 114 to hold the seed material 122 in a desired position. In one embodiment, the seed holder 124 is fabricated from carbon. The attachment of the seed material 122 (i.e., a seed wafer) to the corresponding seed holder 124 within a sublimation system may be made with, for instance, a uniform thermal contact. Various techniques may be used to implement a uniform thermal contact. For example, the seed material 122 may be placed in direct physical contact with the seed holder 124, or an adhesive may be used to fix the seed material 122 to the seed holder 124, so as to ensure that conductive and/or radiative heat transfer is uniform over substantially the entire area between the seed and the seed holder The crystal growth system 112 may include a graphite structure 126 (e.g., a source cap) that may be situated on the source material 120 or at any other location within the crystal growth system 112. The graphite structure 126 (e.g., a source cap) may provide a mechanism for flow of fluid (e.g., vapor or gases) during sublimation of the source material 120. The graphite structure 126 (e.g., a source cap) may filter or otherwise reduce impurities from the source material 120 that may inadvertently sublimate in a crystal growth process. The graphite structure 126 (e.g., a source cap) may have any spatial orientation relative to the source material 120, the seed material 122, and/or the reaction crucible 114. In some embodiments, the reaction crucible 114 or the seed holder 124 may be subjected to the treatment process of the graphite structure 126 according to aspects of the present disclosure. Further, the crystal growth system 112 may optionally include the source material holder 130. The source material holder 130 may be, for example, one or more graphite components within the reaction crucible 114 that brace or support the source material 120. In some embodiments, the source holder 130 may be subjected to the treatment process of the graphite structure 126 according to aspects of the present disclosure. In some embodiments, the source material holder 130 may be attached to the inner walls of the reaction crucible 114, as shown in FIG. 1.

In some embodiments, the graphite structure 126 is a baffle. The baffle may provide a mechanism for the transport of source vapor during sublimation of the source material 120. The baffle may have any spatial orientation relative to the source material 120, the seed crystal 122, and/or the reaction crucible 114. The baffle may filter or otherwise reduce impurities from the source material in a crystal growth process. The baffle may provide for control of radiative heat transfer. The baffle may include any of the baffles disclosed in U.S. patent application Ser. No. 18/962,454 filed on Nov. 27, 2024, which is incorporated herein by reference.

As shown in FIG. 1, the graphite structure 126 may be located on the source material, may be spaced apart from the source material 120 and/or the seed material 126, or may be proximate the seed material 122. In some embodiments, the system 112 may include any number of graphite structures 126 without deviating from the scope of the present disclosure.

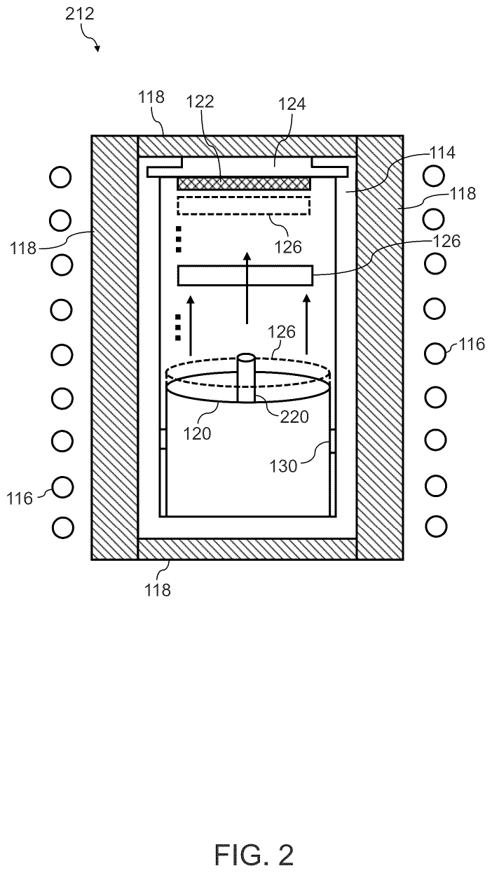

In one example embodiment, shown in FIG. 2, the crystal growth system 132 may be similar to that shown in FIG. 1, but may also include an inlet 134 for introducing a dopant (e.g., N₂) to the reaction crucible 114. The inlet 134, may be, for example, a tube, pipe, vent, or the like. In some embodiments, the source material 120 may surround the inlet 134. For example, in some embodiments, the source material 120 may include a channel through which the inlet 134 is provided. In other embodiments, the source material 120 may include a plurality of subcomponents (attached or detached) which surround the inlet 134. The inlet 134 may be connected to a dopant-containing gas source (not shown) and configured to introduce the dopant-containing gas to the reaction crucible 114. An example of a dopant-containing gas is nitrogen.

The crystal growth system 132 may include the graphite structure 126 (e.g., a source cap) that may be situated within the reaction crucible 114. The graphite structure 126 (e.g., a source cap) may provide a mechanism for flow of fluid (e.g., vapor or gas) during sublimation of the source material 120. The graphite structure 126 (e.g., a source cap) may have any spatial orientation relative to the source material 120, the seed material 122, and/or the reaction crucible 114. The graphite structure 126 (e.g., a source cap) may filter or otherwise reduce impurities from the source material 120 that may inadvertently sublimate in a crystal growth process. In some embodiments, the reaction crucible 114 or the seed holder 124 may be subjected to the treatment process of the graphite structure 126 according to aspects of the present disclosure. In some embodiments, the source material holder 130 may be subjected to the treatment process of the graphite structure 126 according to aspects of the present disclosure.

In some embodiments, the graphite structure 126 is a baffle. The baffle may provide a mechanism for the transport of source vapor during sublimation of the source material 120. The baffle may have any spatial orientation relative to the source material 120, the seed crystal 122, and/or the reaction crucible 114. The baffle may filter or otherwise reduce impurities from the source material in a crystal growth process. The baffle may provide for control of radiative heat transfer. The baffle may include any of the baffles disclosed in U.S. patent application Ser. No. 18/962,454 filed on Nov. 27, 2024, which is incorporated herein by reference.

As shown in FIG. 2, the graphite structure 126 may be located on the source material, may be spaced apart from the source material 120 and/or the seed material 126, or may be proximate the seed material 122. In some embodiments, the system 132 may include any number of graphite structures 126 without deviating from the scope of the present disclosure.

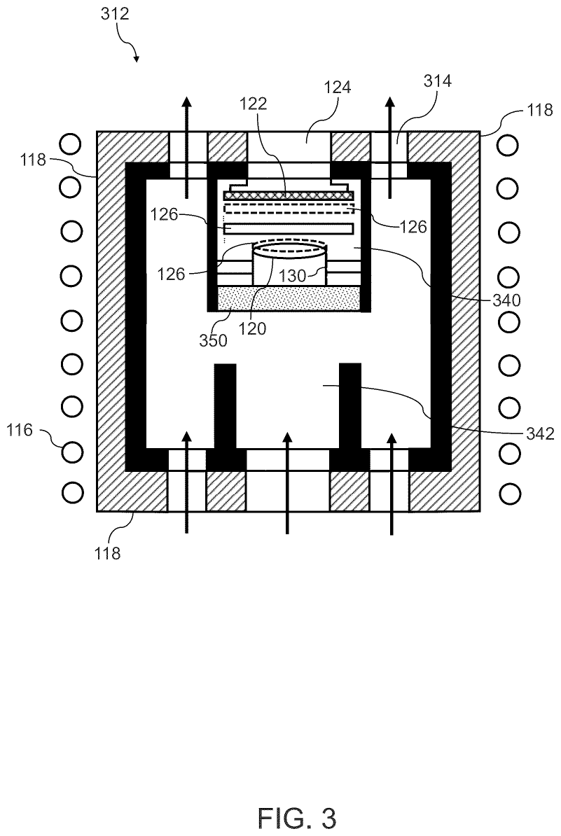

In another example embodiment, shown in FIG. 3, the crystal growth system 142 may be a continuous feed PVT (CF-PVT) system. In a CF-PVT system, such as the crystal growth system 142 of FIG. 3, the reaction crucible may include an upper chamber 144 and a lower chamber 146. The upper chamber 144 may include the source material 120 and the seed material 122. The upper chamber 144 may be separated from the lower chamber 146 by a foamed structure 150. The foamed structure 150 may be formed, for example, from a gas-permeable graphite foam. The source material 120 may be placed on the foamed structure 150 within the upper chamber 144. A gaseous silicon source (e.g., trimethylsilane diluted in argon) may be supplied to the lower chamber 146. As the gaseous silicon source flows through the foamed structure 150, it may react with a carbon source within the foamed structure 150 (e.g., graphite) to form silicon carbide. A CF-PVT system, such as the crystal growth system 142 of FIG. 3, combines a PVT process for the growth of single crystals and high temperature chemical vapor deposition (HTCVD) processes for the in-situ formation and continuous feeding of a high purity polycrystalline source. A CF-PVT system, such as the crystal growth system 142 of FIG. 3, may be particularly useful for growing 3C silicon carbide.

The crystal growth system 142 may include a graphite structure 126 (e.g., a source cap) that may be situated within the upper chamber 144 of the reaction crucible. The graphite structure 126 (e.g., a source cap) may provide a mechanism for flow of fluid (e.g., vapor or fluid) during sublimation of the source material 120. The graphite structure 126 (e.g., a source cap) may filter or otherwise reduce impurities from the source material 120 that may inadvertently sublimate in a crystal growth process. The graphite structure 126 (e.g., source cap) may have any spatial orientation relative to the source material 120, the seed material 122, and/or the upper chamber 144 of the reaction crucible.

In some embodiments, the graphite structure 126 is a baffle. The baffle may provide a mechanism for the transport of source vapor during sublimation of the source material 120. The baffle may have any spatial orientation relative to the source material 120, the seed crystal 122, and/or the reaction crucible 114. The baffle may filter or otherwise reduce impurities from the source material in a crystal growth process. The baffle may provide for control of radiative heat transfer. The baffle may include any of the baffles disclosed in U.S. patent application Ser. No. 18/962,454 filed on Nov. 27, 2024, which is incorporated herein by reference.

As shown in FIG. 3, the graphite structure 126 may be located on the source material, may be spaced apart from the source material 120 and/or the seed material 126, or may be proximate the seed material 122. In some embodiments, the system 132 may include any number of graphite structures 126 without deviating from the scope of the present disclosure.

In some embodiments, the seed holder 124, the upper chamber 144 or the lower chamber 146 of the reaction crucible may be subjected to the treatment process of the graphite structure 126 according to aspects of the present disclosure. In some embodiments, the source material holder 130 may be subjected to the treatment process of the graphite structure 126 according to aspects of the present disclosure. In some embodiments, the foamed structure 150 may be subjected to the treatment process of the graphite structure 126 according to aspects of the present disclosure.

In any of the embodiments shown in FIGS. 1-3, the crystal growth systems 112, 132, 142, and/or the reaction crucible 114 may be implemented in a number of different geometries, or any suitable configurations, and may hold the source material 120 accordingly. Thus, while embodiments of the present disclosure may be illustrated with certain designs of the reaction crucible 114, the scope of the present disclosure is not limited to such designs but will find application in different crystal growth system designs using many different types of reaction crucibles. In some examples, the crystal growth processes (e.g., the processes conducting in any of the embodiments shown in FIGS. 1-3) may be conducted at process temperatures in a range of 1700° C. to about 2600° C.

For any of the crystal growth systems provided herein, one or more parts of the crystal growth system or the source material may be 3D printed, such as disclosed in U.S. Provisional Application Ser. No. 63/689,298, which is incorporated herein by reference.

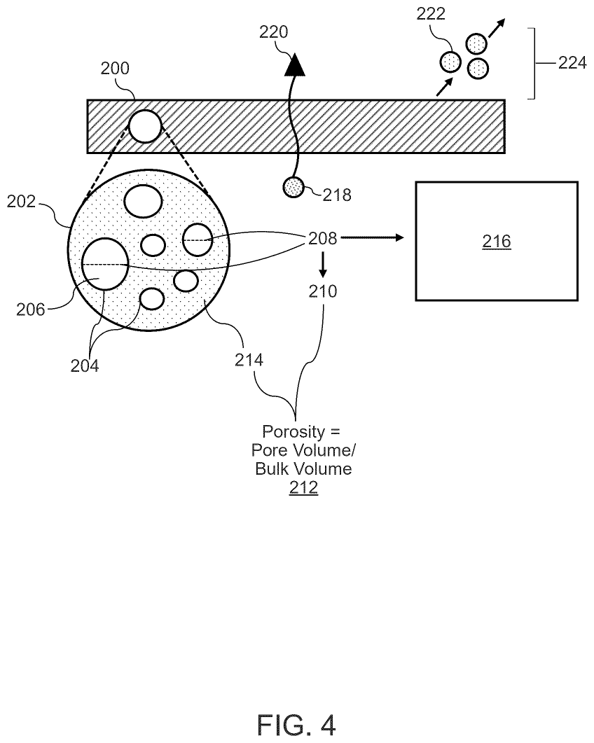

FIG. 4 depicts example characteristics of an untreated graphite structure 200 as a bulk material and by way of a magnified view 202 illustrating the components that make up the microstructure of the untreated graphite structure 200. The untreated graphite structure 200 may include a plurality of pores 204. A pore 206 within the plurality of pores 204 may have a pore size 208 and a pore volume 210. The pore size 208 may be, for instance, the longest dimension (e.g., in any direction) of the pore 206. The presence of the plurality of pores 204 in the untreated graphite structure 200 may lead the untreated graphite structure 200 to exhibit a porosity 212. As used herein, the porosity 212 of the untreated graphite structure 200 is the ratio of the aggregate pore volume 210 for all pores to a bulk volume 214 of the untreated graphite structure 200.

The plurality of pores 204 may have a pore distribution 216 in the untreated graphite structure 200. The pore distribution 216 of the untreated graphite structure 200 may be indicative of the spatial distribution, density, and/or variance of the pores 204 and the pore sizes 208 throughout the untreated graphite structure 200. For instance, a first portion of the untreated graphite structure 200 may have a higher density of the pore sizes 208 that are larger in size relative to a second portion of the untreated graphite structure 200. The pore distribution 216 may have an impact on other characteristics of the untreated graphite structure 200, such as strength, rigidity, a specific surface area of the untreated graphite structure 200, etc.

The untreated graphite structure 200 may have a permeability 220. The permeability 220, as used herein, describes the capability of the untreated graphite structure 200 to allow a fluid 218 (e.g., vapor or gas) to flow through the untreated graphite structure 200. Generally, a material exhibiting a higher permeability may allow the fluid (e.g., vapor or gas) to flow through the material more readily than, for instance, a material exhibiting a lower permeability. Meaning, for instance, if the permeability 220 values of two specimens of the untreated graphite structure 200 were compared, the untreated graphite structure 200 with the highest permeability 220 of the fluid 218 (e.g., vapor or gas) would allow for greater transport of the fluid 218 (e.g., vapor or gas) through the untreated graphite structure 200.

The flow of fluid 218 (e.g., vapor or gas) through the untreated graphite structure 200 in the growth environment established by a crystal growth system, such as the crystal growth systems 112, 132, and 142 of FIG. 1, FIG. 2, and FIG. 3, may lead to an erosion of graphite particles 222 from the untreated graphite structure 200. A particle erosion rate 224 may be defined as a measure of particles lost per a unit of time. In some examples, the particle erosion rate 224 may be measured by a change in the mass of the untreated graphite structure 200 before and after undergoing a crystal growth process.

The particle erosion rate 224 may be influenced by the flow of the fluid 218 (e.g., vapor or gas) through the untreated graphite structure 200. As the fluid 218 (e.g., vapor or gas) flows toward the seed material 122, the fluid 218 (e.g., vapor or gas) may erode the untreated graphite structure 200. The eroded graphite particles 222 may be deposited on the seed material 122, which may increase the number of carbon inclusions and/or aid in the formation of defects or other anomalies in the seed material 122 or a subsequent growth crystal from the seed material 122.

In addition to the permeability characteristics mentioned above (e.g., the porosity 212, the pore distribution 216, the permeability 220, the particle erosion rate 224, etc.), other characteristics of the untreated graphite structure 200 may be relevant to the systems and methods of the present disclosure, such as coefficient of thermal expansion (CTE), strength, purity, resistivity, density, emissivity, thermal conductivity, etc.

Characteristics such as flexural strength of the graphite structure 200 may be impacted by the pore distribution 216. Generally, a material exhibiting the presence of a few, large pores may exhibit a lower flexural strength relative to a material exhibiting a large number of smaller pores, even if both materials exhibit the same porosity. This may be due to the presence of large voids within the bulk of the material.

The purity of the untreated graphite structure 200 may also impact the growth environment of the crystal growth system, such as the crystal growth systems 112, 132, 142 of FIG. 1, FIG. 2, and FIG. 3. The untreated graphite structure 200 may contain non-carbon species, the presence of which may aid in the formation of defects in the seed material 122 or a subsequent growth crystal grown from the seed material 122 during a crystal growth process, particularly if the non-carbon species are eroded from the graphite structure 200 during passage of the fluid 218 (e.g., vapor or gas) through the graphite structure 200.

Resistivity may also be impacted by the microstructure of the untreated graphite structure 200. The untreated graphite structure 200 that exhibits a microstructure where the plurality of pores 204 are open (i.e., exposed, providing an interface between the untreated graphite structure 200 surface and the crystal growth environment) may exhibit a higher resistivity than the untreated graphite structure 200 that exhibits the plurality of pores 204 that are closed (i.e., within the bulk) in the untreated graphite structure 200. Further, closed pores 204 or interconnected pores that include the plurality of pores 204 that intersect one another, (e.g., open, closed, or a combination of open and closed pores 204) may further hinder gas exchange in the untreated graphite structure 200.

The illustration provided in FIG. 4 is for descriptive purposes only. Those of ordinary skill in the art, using the disclosures provided herein, will understand that aspects of the present disclosure may encompass a wide variety of microstructures and/or characteristics that may be found in the untreated graphite structure 200.

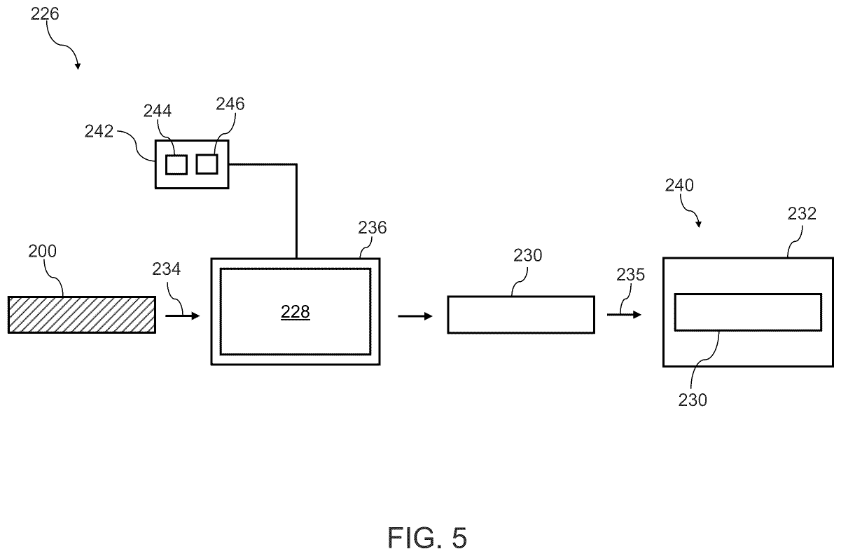

FIG. 5 provides an overview of an example method 226 for performing a treatment process 228 on the untreated graphite structure 200, to produce a treated graphite structure 230 that may be provided to a crystal growth system 232, such as the crystal growth system 112, 132, 142 of FIG. 1, FIG. 2, and FIG. 3, according to examples of the present disclosure.

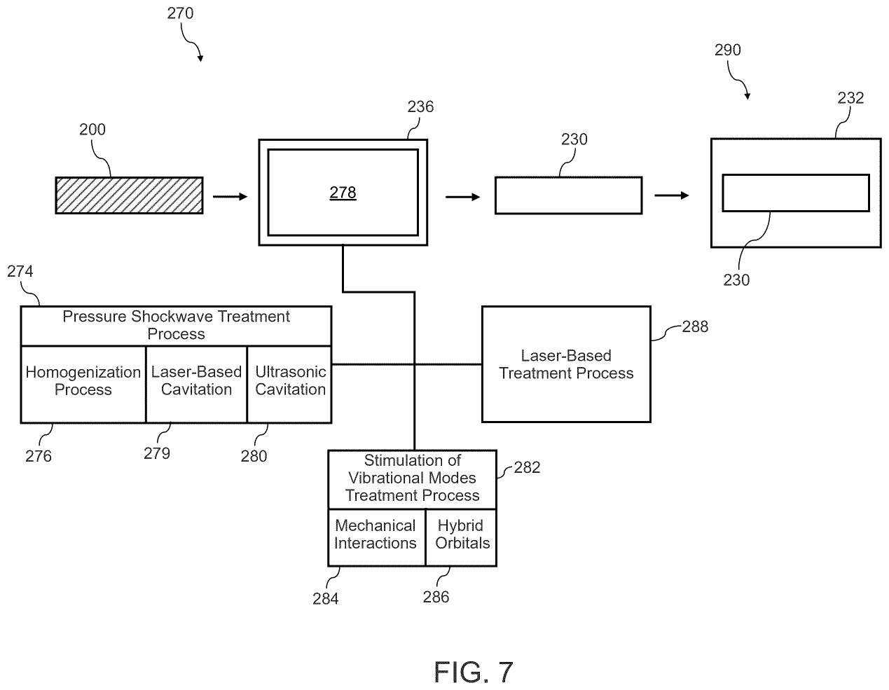

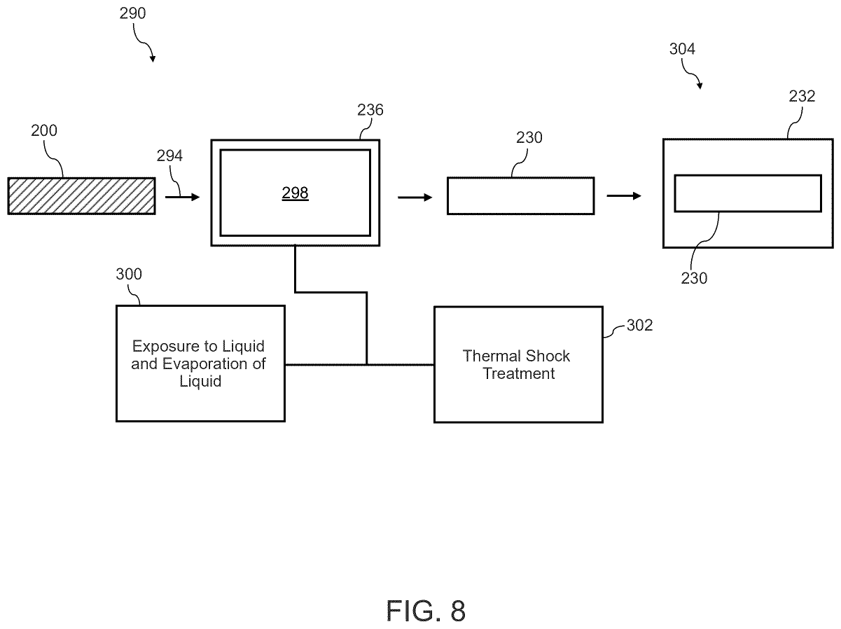

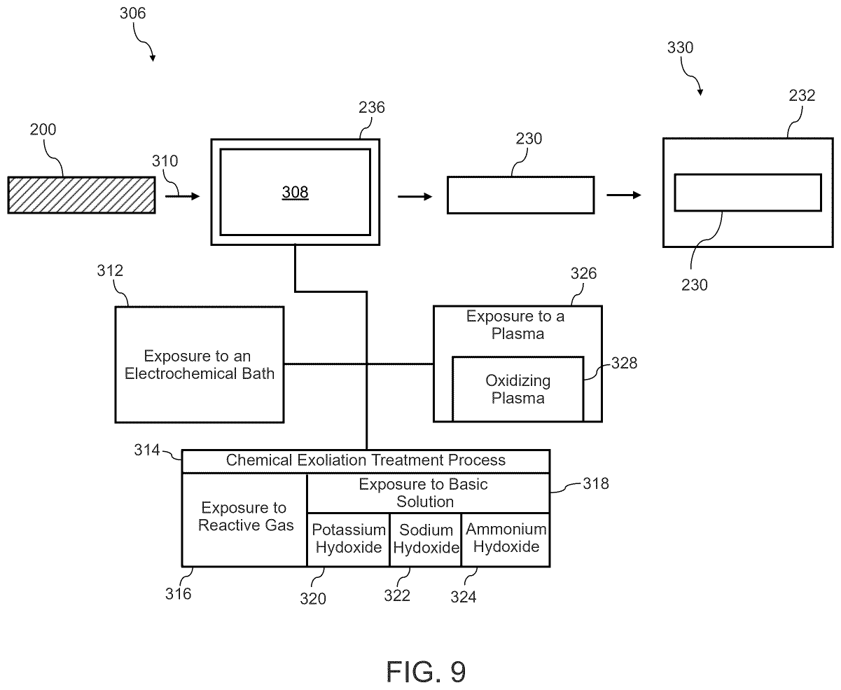

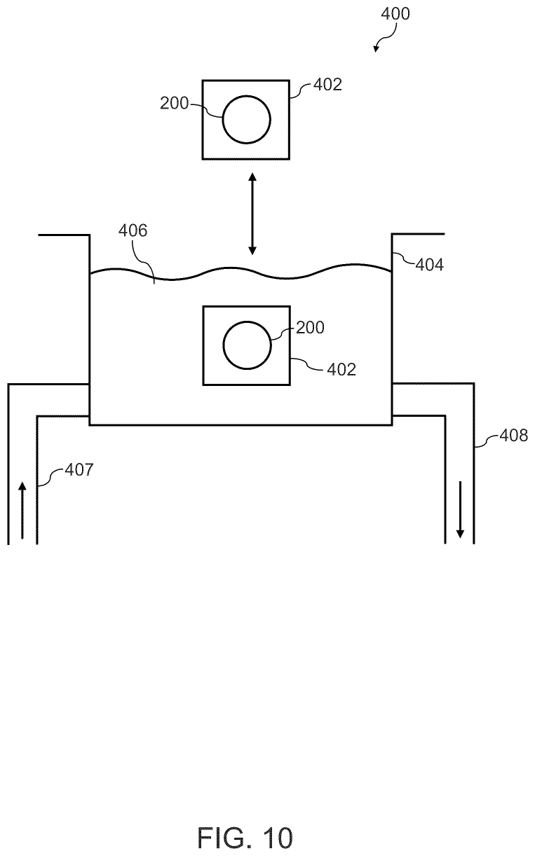

At 234, the example method 226 may include providing the untreated graphite structure 200 to a treatment platform 236 where a treatment process 228 may be performed on the untreated graphite structure 200. The treatment platform 236 is any system operable to perform any of the treatment processes 228 provided herein. Example treatment platforms are shown in FIGS. 10, 11, and 12. The treatment process 228 may be a mechanical treatment process 278, a physical treatment process 298, or a chemical treatment process 308 which are discussed in detail below and in FIG. 7, FIG. 8, and FIG. 9, respectively. The treatment process 228 may alter one or more characteristics (e.g., the porosity 212, the pore distribution 216, the permeability 220, the particle erosion rate 224, etc.) of the untreated graphite structure 200, producing the treated graphite structure 230. In some examples, the treatment process 228 may modify one or more characteristics of the entirety of the untreated graphite structure 200. In some examples, the treatment process 228 may selectively modify one or more characteristics at a specific depth or location of the untreated graphite structure 200. That is, depending on the treatment process 228 employed, the one or more characteristics of the entire untreated graphite structure 200 may be altered, or the one or more characteristics at the surface of the untreated graphite structure 200 may be altered, or the one or more characteristics at or to a specific depth within the untreated graphite structure 200 may be altered. The treated graphite structure 230 may then be provided to the crystal growth system 232 as indicated by arrow 235.

In some aspects, at least a portion of the treated graphite structure 230 may have an exposed graphite surface within the crystal growth system 232. In other words, there may be no coating on the treated graphite structure 230 such that the treated graphite structure includes a graphite surface that is exposed to the environment within the crystal growth system 232. This is possible due to, for instance, a reduced particle erosion rate 224 of the treated graphite structure 230. A crystal growth process may be conducted at 240.

Aspects of the present disclosure are discussed with conducting a treatment process with no subsequent coating such that the graphite structure has an exposed graphite surface. In some examples, the treatment processes disclosed herein may be used in combination with a coating. The coating may impart additional benefits to the exposed graphite surface of the treated graphite structures, such as, by non-limiting example, an increased melting point, enhanced chemical stability, alterations to density, and so forth. The coating may impart additional beneficial properties to the treated graphite structure without altering the underlying material characteristics and properties (i.e., the coating may impart additional resistance to processing conditions without altering the characteristics or properties of the underlying treated graphite structure). This coating can include, for instance, a pyrolytic carbon coating or tantalum carbide (TaC). In some examples, the treatment process may be implemented as a pretreatment process on the graphite structure, such as a pretreatment process of the graphite structure prior to application of a coating. In some examples, the treatment process may be a post-treatment process performed after application of a coating.

As shown in FIG. 5, in some embodiments, the treatment platform 236 is coupled to control circuitry including one or more control devices, such as a controller 242. The controller 242 may include one or more processors 244 and one or more memory devices 246. The one or more memory devices 246 may store computer-readable instructions that when executed by the one or more processors 244 cause the one or more processors 244 to perform one or more control functions, such as any of the functions described herein. The controller 242 may be in communication with various other aspects of the treatment platform 236 through one or more wired and/or wireless control links. The controller 242 may send control signals to various components of the treatment platform 236 to implement the treatment process 228 on the untreated graphite structure 200.

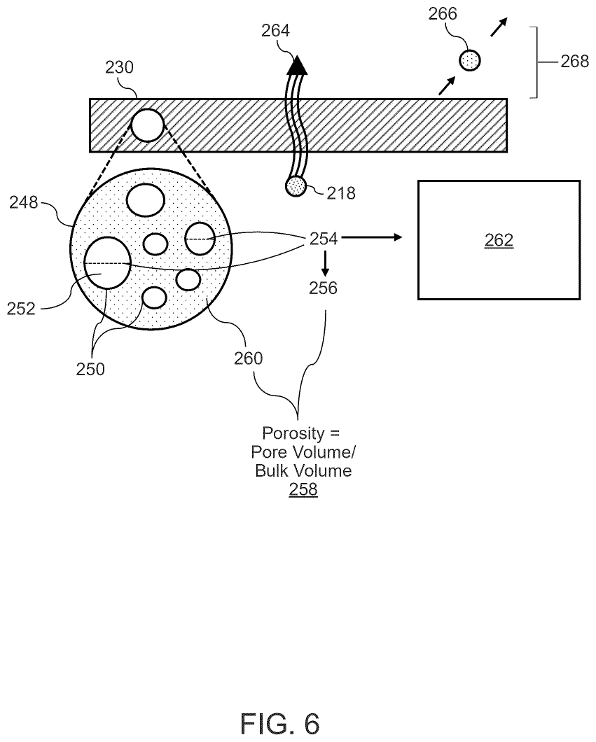

FIG. 6 depicts example characteristics of the treated graphite structure 230 as a bulk material and by way of a magnified view 248 illustrating the components that make up the microstructure of the treated graphite structure 230. The treated graphite structure 230 may contain a plurality of pores 250 that may have been altered by the treatment process 228 from the plurality of pores 204 of the untreated graphite structure 200. A pore 252 within the plurality of pores 250 may have a pore size 254 and a pore volume 256. The pore size 254 may be, for instance, the longest dimension (e.g., in any direction) of the pore 252. The pore size 254 and the pore volume 256 may differ from the pore size 208 and pore volume 210 of the untreated graphite structure 200. The alteration of the of the plurality of pores 250 in the treated graphite structure 230 may lead the treated graphite structure 230 to exhibit a porosity 258. As used herein, the porosity 258 of the treated graphite structure 230 is the ratio of the aggregate pore volume 256 of all pores 252 to a bulk volume 260 of the treated graphite structure 230. In some examples, the porosity 258 of the treated graphite structure 230 provides insight into a permeability 264 of the treated graphite structure 230.

The plurality of pores 250 may have a pore distribution 262 in the treated graphite structure 230. The pore distribution 262 of the treated graphite structure 230 may change from the pore distribution 216 of the untreated graphite structure 200 after undergoing the treatment process 228. For instance, the untreated graphite structure 200 may have a density of the pore sizes 208 that are smaller in size relative to the treated graphite structure 230. In some examples, the plurality of pores 250 may be homogenized to provide a more uniform size distribution throughout the treated graphite structure 230. The pore distribution 262 may have an impact on other characteristics of the treated graphite structure 230, such as strength, rigidity, a specific surface area of the treated graphite structure 230, etc. For example, the treated graphite structure 230 may have an increase to the specific surface area as compared to the untreated graphite structure 200. The plurality of pores 250 may lead to an increase in the specific surface area of the treated graphite structure 230, or the surface area of the treated graphite structure 230 relative to the mass, bulk volume, or geometry of the treated graphite structure 230. The specific surface area of the treated graphite structure 230 may be modified relative to the specific surface area of the untreated graphite structure 200 by a factor of 1.1 to 1000, such as 1.1 to 2, such as 2 to 100, such as 100 to 1000.

The treated graphite structure 230 may have the permeability 264 and a particle erosion rate 268. As a result of the treatment process, the permeability 264 of the treated graphite structure 230 may be modified relative to the untreated graphite structure 200. In some embodiments, the permeability 264 of the treated graphite structure 230 may be altered by the treatment process 228 such that a difference between the permeability 264 of the treated graphite structure 230 and the untreated graphite structure 200 is between about 1% to 10%, or about 10% to about 50%, or over 50%. For instance, the permeability 264 of the treated graphite structure 230 may be increased relative to the permeability of the untreated graphite structure 200. In some examples, the permeability 264 of the treated graphite structure 230 may be decreased relative to the permeability of the untreated graphite structure 200.

As a result of the treatment process 228, the particle erosion rate 268 for the treated graphite structure 230 may be modified relative to the particle erosion rate 224 of the untreated graphite structure 200. For instance, the particle erosion rate 268 for the treated graphite structure 230 may be lower relative to the particle erosion rate 224 for the untreated graphite structure 200, which may lead to a reduction in carbon inclusions and/or the formation of defects or other anomalies in the seed material 122, or a subsequent growth crystal grown from the seed material 122. As such, the treatment process 228 may result in the reduced particle erosion rate 268 associated with the flow of the fluid 218 (e.g., vapor or gas) through the treated graphite structure 230 relative to an untreated graphite structure 200.

In addition to the permeability characteristics mentioned above (e.g., the porosity 258, the pore distribution 262, the permeability 264, the rate of particle erosion 268, etc.), other characteristics of the treated graphite structure 230 may be relevant to the systems and methods of the present disclosure, such as coefficient of thermal expansion (CTE), strength, purity, resistivity, density, emissivity, thermal conductivity, etc. These characteristics may be modified by the treatment process.

For instance, spacing between parts in a system (e.g., crystal growth system or deposition system) may be modified and/or controlled by treating one or more graphite structures to modify a coefficient of thermal expansion (CTE) for the graphite structure. A treated graphite structure may have a different CTE relative to an untreated graphite structure. In this way, the coefficient of thermal expansion can be modified using a treatment process according to examples of the present disclosure to provide controlled gaps and tolerances in a crystal growth system or deposition system.

For instance, the flexural strength may be impacted by altering the pore distribution 216 of the untreated graphite structure 200 to the pore distribution 262 of the treated graphite structure 230. Resistivity may also be impacted by the treatment process 228 altering the microstructure of the treated graphite structure 230. The treatment process may also remove impurities such that the treated graphite structure 230 has a higher purity relative to the untreated graphite structure 200. In some examples, the treated graphite structure 230 may contain less than 10 ppm of impurities by weight relative to the weight of the treated graphite structure 230, such as about 1-10 ppm impurity by weight, such as about 0-5 ppm impurity by weight, such as about 0-2 ppm impurity by weight, such as about less than 1 ppm impurity by weight.

The illustration provided in FIG. 6 is for descriptive purposes only. Those of ordinary skill in the art, using the disclosures provided herein, will understand that aspects of the present disclosure may encompass a wide variety of microstructures and/or characteristics that may be found in the treated graphite structure 230.

FIG. 7 provides an overview of an example method 270 for performing a mechanical treatment process 278 on the untreated graphite structure 200 to produce a treated graphite structure 230 that may be provided to a crystal growth system 232, such as the crystal growth systems 112, 132, and 142 of FIG. 1, FIG. 2, and FIG. 3.

At 272, the example method 270 may include providing the untreated graphite structure 200 to the treatment platform 236 where the mechanical treatment process 278 may be performed on the untreated graphite structure 200. The treatment platform 236 is any system operable to perform any of the mechanical treatment processes 278 provided herein, such as a treatment platform operable to provide pressure shockwaves to the untreated graphite structure 200.

In some embodiments, the mechanical treatment process 278 may include a pressure shockwave treatment process 274. The pressure shockwave treatment process 274 may include a homogenization treatment process 276, such as, by non-limiting example, a high-pressure homogenization process. The homogenization treatment process 276 may be a liquid-phase exfoliation process and may pass untreated graphite structures 200 through an orifice under pressure to produce treated graphite structures 230 and open the pores 206 that may be closed in the interior of the untreated graphite structure 200 to produce the treated graphite structure 230 with a more uniform pore size distribution.

In some embodiments, the pressure shockwave treatment process 274 may be a laser-based cavitation treatment process 279. The laser-based cavitation treatment process 279 may include providing the untreated graphite structure 200 in a liquid. The laser-based cavitation process 279 may the target the emission of laser (e.g., pulsed laser emissions) at a localized area within the liquid, which may induce shockwave cavitation bubbles and exfoliate the surface of the untreated graphite structure 200. Thus, the laser-based cavitation treatment process 279 may remove material from the surface of the untreated graphite structure 200 and may alter the pore sizes 208 and/or the pore volumes 210 of the untreated graphite structure 200 to produce the treated graphite structure 230.

The pressure shockwave treatment process 274 may include an ultrasonic treatment process 280. The ultrasonic treatment process 280 may include the agitation of a liquid through high-frequency vibrations, which may provide a pressure difference needed to penetrate the pores 206 of the untreated graphite structure 200. Thus, the ultrasonic treatment process 280 may alter the pore sizes 208 and/or the pore volumes 210 of the untreated graphite structure 200, producing the treated graphite structure 230. Further, the ultrasonic treatment process 280 may cleanse the untreated graphite structure 200 of impurities during the ultrasonic treatment process 280.

In some embodiments, the mechanical treatment process 278 may include a stimulation of vibrational modes treatment process 282. In some embodiments, the stimulation of vibrational modes treatment process 282 may include providing the untreated graphite structure 200 in a fluid and transferring vibrational energy to the untreated graphite structure 200 through the fluid. In some embodiments, the stimulation of vibrational modes treatment process 282 may include providing the untreated graphite structure 200 to a solid interface that imparts vibrational motion. In some embodiments, the stimulation of vibrational modes treatment process 282 may include transferring vibrational energy to the untreated graphite structure 200 with electrical or electromagnetic radiation. The stimulation of vibrational modes treatment process 282 may include imparting mechanical interactions 284 on the lattice of the untreated graphite structure 200 to overcome bond energies within the lattice of the untreated graphite structure 200. The mechanical interactions treatment process 284 may cleave or otherwise alter the structure of the untreated graphite structure 200, exposing or interconnecting the pores 206 within the interior of the untreated graphite structure 200, producing the treated graphite structure 230.

The stimulation of vibrational modes treatment process 282 may include introducing a species to the lattice of the untreated graphite structure 200 to hybridize 286 and/or functionalize the surface of the untreated graphite structure 200, which may assist in overcoming associated bond energies within the lattice of the untreated graphite structure 200. Other treatment processes 228, such as the stimulation of vibrational modes treatment process 282 involving imparting mechanical interactions 284 to the lattice of the untreated graphite structure 200, may be used in conjunction with the hybridization 286 and/or functionalization treatment process to produce the treated graphite structure 230.

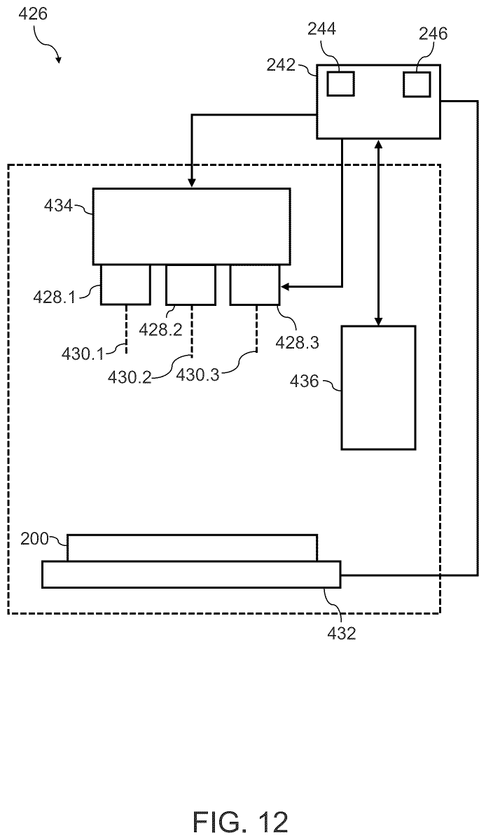

In some embodiments, the mechanical treatment process 278 may include a laser-based treatment process 288. The laser-based treatment process 288 may include the application of lasers (e.g., pulsed laser emissions) to the surface of the untreated graphite structure 200 to ablate the surface of the untreated graphite structure 200 and alter pore structures, such as the pore size 208 and/or the pore volume 210. Further, alterations to the surface of the untreated graphite structure 200 may alter the emissivity of the untreated graphite structure 200. For instance, the laser-based treatment process 288 that increases the surface roughness of the untreated graphite structure may increase the emissivity of the untreated graphite structure 200, producing the treated graphite structure 230. An example laser-based treatment system 426 is discussed below and in FIG. 12.

The treated graphite structure 230 may then be provided to the crystal growth system 232, and at least a portion of the treated graphite structure 230 may have an exposed graphite surface within the crystal growth system 232. A crystal growth process may be conducted at 290.

FIG. 8 provides an overview of an example method 292 for performing a physical treatment process 298 on the untreated graphite structure 200 to produce a treated graphite structure 230 that may be provided to a crystal growth system 232, such as the crystal growth systems 112, 132, 142 of FIG. 1, FIG. 2, and FIG. 3.

At 294, the example method 292 may include providing the untreated graphite structure 200 to the treatment platform 236 where the physical treatment process 298 may be performed on the untreated graphite structure 200. The treatment platform 236 is any system operable to perform any of the physical treatment processes 298 provided herein.

In some embodiments, the physical treatment process 298 may include an evaporative treatment process 300. The evaporative treatment process 300 may include exposing the untreated graphite structure 200 to a liquid, whereby the liquid may then be removed through evaporative processes. The evaporative treatment process may be used to alter impurities in the untreated graphite structure 200.

In some embodiments, the physical treatment process 298 may include a thermal treatment process 302. The thermal treatment process 302 may include heating the untreated graphite structure 200 at specific pressures to a temperature in a range of 50° C. to about 130° C. to polymerize infiltrated or adsorbed materials. In some embodiments, the thermal treatment process 302 may include heating the untreated graphite structure 200 to a temperature in a range of about 25° C. to about 80° C. to conduct dry-cleaning processes. In some embodiments, the thermal treatment process 302 may include heating the untreated graphite structure 200 to a temperature in a range of about 60° C. to about 180° C. to rapidly evaporate solvents, such as organic solvents, water, or alcohols. In some embodiments, the thermal treatment process 302 may include heating the untreated graphite structure 200 to a temperature in a range of about 100° C. to about 300° C. to evaporate higher molecular weight organics. In some embodiments, the thermal treatment process 302 may include heating the untreated graphite structure 200 to a temperature in a range of about 300° C. to about 2000° C. to oxidize, desorb chemisorbed matter, or sinter the graphite structure. In some examples, the thermal treatment process 302 may include heating the untreated graphite structure 200 to a temperature in a range of about 2000° C. to about 3000° C. to recrystallize the untreated graphite structure 200. As such, the ramp rate and duration of the thermal treatment process 302 may control the effects of the thermal treatment process 302 and/or the depth at which the microstructure of the untreated graphite structure 200 is altered.

The thermal treatment process 302 may employ various mechanisms to implement heating such as, by non-limiting example, convection heating, contact heating using a fluid or hot interface, heating caused by frictional forces, heating caused by vibrations of the molecules within the untreated graphite structure 200 (e.g., acoustic vibrations or mechanical deformation), and/or electromagnetic radiation including X-ray radiation, ultraviolet radiation, black body radiation, infrared radiation, microwave frequency, or radio frequency.

The thermal treatment process 302 may exploit alterations of the pore sizes 208 and/or the pore volumes 210 of the untreated graphite structure 200 due to thermal expansion, altering the pore sizes 208 and/or the pore volumes 210 of the untreated graphite structure 200 to produce the treated graphite structure 230.

The treated graphite structure 230 may then be provided to the crystal growth system 232, and at least a portion of the treated graphite structure 230 may have an exposed graphite surface within the crystal growth system 232. A crystal growth process may be conducted at 304.

FIG. 9 provides an overview of an example method 306 for performing a chemical treatment process 308 on the untreated graphite structure 200 to produce a treated graphite structure 230 that may be provided to a crystal growth system 232, such as the crystal growth systems 112, 132, and 142 of FIG. 1, FIG. 2, and FIG. 3.

At 310, the example method 306 may include providing the untreated graphite structure 200 to the treatment platform 236 where the chemical treatment process 308 may be performed on the untreated graphite structure 200. The treatment platform 236 is any system operable to perform any of the chemical treatment processes 308 provided herein.

In some embodiments, the chemical treatment process 308 may include a chemical bath treatment process 312. The chemical bath treatment process 312 (e.g., electrochemical bath) may include exposing the untreated graphite structure 200 to an etchant capable of etching the pores 206 of the untreated graphite structure 200, interconnecting and altering the pore sizes 208 and/or the pore volumes 210 of the untreated graphite structure 200 and producing the treated graphite structure 230. In some examples, the etchant may include, for instance, aqueous potassium nitrate, oxygen, hydrogen, a forming gas, sulfuric acid, or other etchant. In some examples, the chemical bath treatment process may be an electrochemical bath treatment process. However, other suitable etchants may be used without deviating from the scope of the present disclosure.

In some embodiments, the chemical treatment process 308 may include providing the untreated graphite structure 200 in a basic solution 318 (e.g., as a chemical bath). Similarly to the reactive gas 316 treatment process, the basic solution 318 treatment process may alter the pore size 208 and/or the pore volume 210 of the untreated graphite structures, which may be due to untreated graphite structures 200 having limited corrosion resistance against bases (e.g., amines, caustic soda, etc.).

In some embodiments, exposure to the basic solution 318 may include at least partially submerging the untreated graphite structure 200 in the basic solution 318. In some embodiments, exposure to the basic solution 318 may include exposure of the untreated graphite structure 200 to a vapor from a basic solution 318. In some embodiments, exposure to the basic solution 318 may include coating (e.g. spray-coating, spin coating, manual application of the basic solution 318 using tools, etc.) the untreated graphite structure 200 with a basic solution 318. The basic solution 318 may contain potassium hydroxide 320, sodium hydroxide 322, or ammonium hydroxide 324. However, other basic solutions can be used without deviating from the scope of the present disclosure. An example chemical bath treatment platform 400 is discussed below and in FIG. 10.

In some embodiments, the chemical treatment process 308 may include a chemical exfoliation treatment process 314. In some embodiments, the chemical exfoliation treatment process 314 may include exposing the untreated graphite structure 200 to a reactive gas 316 (e.g., corrosive gas) capable of reacting with the untreated graphite structure 200, which may interconnect and/or alter the pore sizes 208 and/or the pore volumes 210 of the untreated graphite structure 200, producing the treated graphite structure 230. An example of the reactive gas 316 is bromine (Br₂), however, other gases (e.g., corrosive gases) may be used without deviating from the scope of the present disclosure.

In some embodiments, the chemical treatment process 308 may include a plasma-based treatment process 326. The plasma-based treatment process 326 may include a high-frequency electromagnetic field to break the bonds of a reactive gas, such as hydrogen gas, forming a plasma of reactive radicals and ions. Interactions among the radicals and/or ions at the interface between the plasma and the untreated graphite structure 200 may cause progressive etching of the surface as exposure to the plasma is increased. This etching may remove material from the untreated graphite structure 200, which may interconnect and/or alter the pore sizes 208 and/or the pore volumes 210 of the untreated graphite structure 200, producing the treated graphite structure 230.

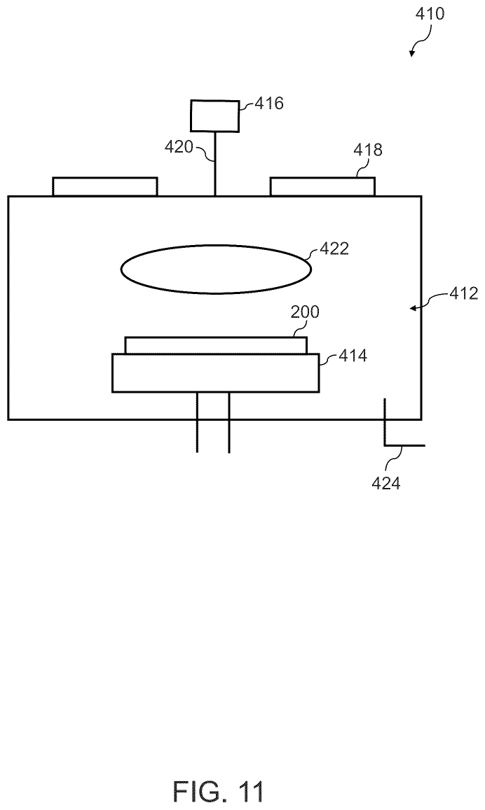

In some examples, the plasma-based treatment process 326 may include an oxidizing plasma 328. The oxidizing plasma 328 treatment process, like the plasma-based treatment process 326, may include the generation of a plasma using oxygen gas. The oxidizing plasma may remove material from untreated graphite structure 200, which may interconnect and/or alter the pore sizes 208 and/or the pore volumes 210 of the untreated graphite structure 200. In addition, the oxidizing plasma 328 treatment process may functionalize an exposed interface of the untreated graphite structure 200 with oxygen, which may form more oxide surface relative to the plasma-based treatment process 326. The formation of the oxide surface due to the oxidizing plasma 328 treatment process may increase lattice strain and chemical reactivity of the treated graphite structure 230, where further application of any of the treatment processes 228 disclosed herein may be performed. An example plasma-based treatment system 410 is discussed below and in FIG. 11.

The treated graphite structure 230 may then be provided to the crystal growth system 232, and at least a portion of the treated graphite structure 230 may have an exposed graphite surface within the crystal growth system 232. A crystal growth process may be conducted at 330.

FIG. 10 depicts a cross-section view of an example treatment platform 400 that may be operable to implement many of the treatment processes described herein, such as a chemical bath treatment process, mechanical treatment process, etc. The treatment platform 400 may include workpiece holder 402 may be operable to hold the untreated graphite structure 200.

The workpiece holder 402 may be configured to provide the untreated graphite structure 200 into a bath 404 (e.g., liquid, wet chemical etchant, basic solution, electrochemical bath) so that the untreated graphite structure 200. Other suitable techniques or systems for exposing the untreated graphite structure 200 to the liquid in the bath (e.g., liquid, wet chemical etchant, basic solution, electrochemical bath) may be used (e.g., a spray system) without deviating from the scope of the present disclosure. The liquid 406 may be provided into (e.g., flowed into) the bath 404 through an inlet 407 and may be provided from the bath (e.g., flowed out of) through an outlet 408.

FIG. 11 depicts an example plasma-based treatment system 410 operable to provide a plasma-based treatment process 326 on the untreated graphite structure 200 according to examples of the present disclosure. The plasma-based treatment system 410 includes a chamber 412, a workpiece support 414, a process gas source 416, and a plasma source 418. The workpiece support 414 may include a chuck (e.g., electrostatic chuck) or other mechanism to hold the untreated graphite structure 200 in place during a plasma-based treatment process 326. The process gas source 416 may be operable to deliver a process gas to the chamber 412, for instance, using a gas delivery outlet 420 (e.g., showerhead). The plasma source 418 may be configured to induce a plasma 422 in the process gas. The process gas may be exhausted from the chamber 412 through exhaust system 424. The plasma 422 is used to modify the untreated graphite structure 200. The plasma source 418 may be, for instance, one or more of an inductively coupled plasma source, capacitively coupled plasma source, microwave plasma source, transformer coupled plasma source, helicon wave plasma source, etc. or combination of any of the foregoing sources.

FIG. 12 depicts an example laser-based treatment platform 426 according to examples of the present disclosure. The laser-based treatment platform 426 may be configured to implement one or more aspects of the present disclosure, such as the laser-based treatment process 288.

The laser-based treatment platform 426 includes one or more laser sources 428.1, 428.2, 428.3, . . . , 428.n. The one or more laser sources 428.1, 428.2, 428.3, . . . , 428.n may each be configured to respectively emit a laser 430.1, 430.2, 430.3, . . . , 430.n in accordance with various laser parameters. The laser parameters may include, for instance, focusing depth, laser power, laser wavelength, laser pulse duration, laser pulse frequency, laser pulse energy, etc.

The laser sources 428.1, 428.2, 428.3, . . . , 428.n may each be associated with one or more wavelengths and may be, for instance, one or more of an excimer laser, UV laser, visible light laser, infrared laser, single wavelength laser, multiwavelength laser, white laser, etc. The laser sources 428.1, 428.2, 428.3, . . . , 428.n may each be associated with a pulse duration and may be, one or more of an attosecond laser, femtosecond laser, nanosecond laser, etc. The laser sources 428.1, 428.2, 428.3, . . . , 428.n may each be associated with a lasing medium and may be, for instance, a gas (e.g., CO₂) laser, solid state laser (e.g., GaN, AlGaN, YAG, etc.), diode laser, fiber laser, etc. The laser sources 428.1, 428.2, 428.3, . . . , 428.n may be one or more of a single frequency laser, frequency doubled laser, frequency tripled laser, frequency quadrupled laser, etc.

The laser sources 428.1, 428.2, 428.3, . . . , 428.n may each be the same type of laser source or different types of laser sources. The laser sources 428.1, 428.2, 428.3, . . . , 428.n may be configured to emit lasers 430.1, 430.2, 430.3, . . . , 430.n in accordance with the same laser parameters or different laser parameters.

For instance, in some embodiments, the laser-based treatment system 426 may include a first laser source 428.1, a second laser source 428.2, and a third laser source 428.3. The first laser source 428.1 may be operable to emit a laser 430.1 with laser parameters sufficient to perform a treatment process. The second laser source 428.2 may be operable to emit a laser 430.2 with laser parameters sufficient to perform a coarse laser ablation process. In some embodiments, the second laser source 428.2 may be an infrared laser source configured to emit an infrared laser.

The third laser source 428.3 may be configured to emit a laser 430.3 with laser parameters sufficient to perform a fine laser ablation process. In some embodiments, the third laser source 428.3 may be an ultraviolet laser source configured to emit an ultraviolet laser.

FIG. 12 depicts three laser sources 428.1, 428.2, 428.3 for purposes of illustration and discussion. Those of ordinary skill in the art, using the disclosures provided herein, will understand that the laser-based treatment system 426 may include more or fewer laser sources without deviating from the scope of the present disclosure.

The laser-based treatment platform 426 includes a workpiece support 432 configured to support the untreated graphite structure 200. The workpiece support 432 may include a chuck (e.g., vacuum chuck) or other mechanism to hold the untreated graphite structure 200 in place during laser processing according to examples of the present disclosure.

The one or more laser sources 428.1, 428.2, 428.3, . . . , 428.n may be coupled to a translation stage 434 that may move the one or more laser sources 428.1, 428.2, 428.3, . . . , 428.n relative to the untreated graphite structure 200. In addition, the laser sources 428.1, 428.2, 428.3, . . . , 428.n and/or translation stage 434 may include one or more optics (e.g., lens, mirrors, etc.) to facilitate moving the emission of the laser 430.1, 430.2, 430.3, . . . , 430.n from the laser sources 428.1, 428.2, 428.3, . . . , 428.n relative to the untreated graphite structure 200. In addition, or in the alternative, the workpiece support 432 may be operable to move the untreated graphite structure 200 relative to the one or more laser sources 428.1, 428.2, 428.3, . . . , 428.n In this way, the laser-based treatment system 426 may be able to control the translation stage 434 and/or the workpiece support 432 to impart relative motion between the emission of the laser 430.1, 430.2, 430.3, . . . , 430.n and the untreated graphite structure 200 to implement laser-based removal processes and/or laser ablation processes according to examples of the present disclosure.

In some embodiments, the laser-based treatment platform 426 may additionally include one or more sensors 436 for obtaining data associated with the untreated graphite structure 200, such as workpiece property data for the untreated graphite structure 200. The workpiece property data may include, for instance, data associated with a surface of the untreated graphite structure 200 (e.g., topography, roughness), subsurface regions of the untreated graphite structure 200, temperature of the untreated graphite structure 200, or other parameters.

In some embodiments, the one or more sensors 436 may include, for instance, an optical sensor, such as an image capture device (e.g., camera) that may capture images at one or more wavelengths of visible light and/or ultraviolet or infrared light. In some embodiments, the one or more sensors 436 may include one or more surface measurement lasers that may be operable to emit a laser onto the surface of the untreated graphite structure 200 and scan the surface (based on reflections of the laser) for depth measurements, topography measurements, etc. of the surface of the untreated graphite structure 200. Other suitable sensors 436 may be used without deviating from the scope of the present disclosure.

The laser-based treatment system 426 may include one or more control devices, such as the controller 242 of FIG. 5. The controller 242 may include one or more processors 244 and one or more memory devices 246. The one or more memory devices 246 may store computer-readable instructions that when executed by the one or more processors 244 cause the one or more processors 244 to perform one or more control functions, such as any of the functions described herein. The controller 242 may be in communication with various other aspects of the laser-based treatment system 426 through one or more wired and/or wireless control links. The controller 242 may send control signals to the various components of the laser-based treatment system 426 (e.g., the laser sources 428.1, 428.2, 428.3, . . . , 428.n, the workpiece support 432, the sensor 436) to implement a laser-based treatment process 288 on the untreated graphite structure 200.

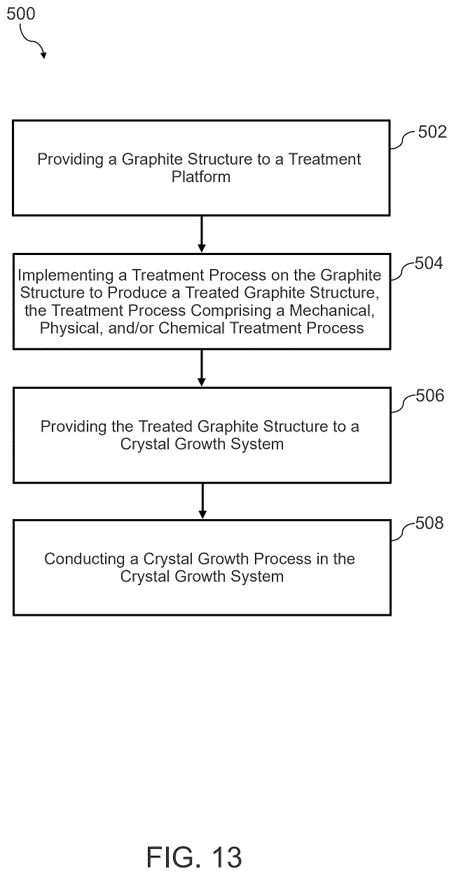

In some embodiments, the controller 242 may control aspects of the laser-based treatment system 426 (e.g., the laser sources 428.1, 428.2, 428.3, . . . , 428.n) based at least in part on data from the sensor(s) 436. For instance, the controller 242 may adjust various laser parameters for the emission of the laser 430.1, 430.2, 430.3, . . . , 430.n from the laser sources 428.1, 428.2, 428.3, . . . , 428.n based at least in part on data from the sensor(s) 436. The laser parameters may include, for instance, one or more of focusing depth, laser power, laser wavelength, laser pulse duration, laser pulse frequency, laser pulse energy, scan pattern, and/or translation speed. In some embodiments, the laser parameters may include incidence angle of the emission of the laser 428.1, 428.2, 428.3, . . . , 428.n on the untreated graphite structure 200. The controller 242 may be configured to adjust the laser parameters based on sensor data associated with a the untreated graphite structure 200 undergoing a laser-based surface processing operation (e.g., dynamic adjustment during or after a laser-based surface processing operation). In some embodiments, the laser sources 428.1, 428.2, 428.3, . . . , 428.n may include an adaptive optics system that may include one or more lenses, mirrors, or other optical devices. The lenses, mirrors, or other optical devices may be moved or adjusted to adjust one or more of the one or more laser parameters. For instance, the one or more lenses may be swapped or adjusted to change a focal depth of the emission of the laser 428.1, 428.2, 428.3, . . . , 428.n FIG. 13 depicts a flow chart diagram of an example method 500 according to example aspects of the present disclosure. The method 500 includes operations illustrated in a particular order for purposes of illustration and discussion. Those of ordinary skill in the art, using the disclosures provided herein, will understand that the various steps or operations of any of the method provided in this disclosure may be adapted, rearranged, omitted, include steps not illustrated, and/or modified in various ways without deviating from the scope of the present disclosure.

At 502, the method 500 includes providing an untreated graphite structure to a treatment platform. An example untreated graphite structure is discussed with reference to FIG. 4.

At 504, the method 500 includes implementing a treatment process on the untreated graphite structure to alter one or more characteristics of the untreated graphite structure, producing a treated graphite structure. The treatment process includes one or more of a chemical treatment process, a mechanical treatment process, and/or a physical treatment process. For instance, in some examples, the treatment process may be a pressure shock wave treatment process. In some examples, the pressure shock wave treatment process may be a homogenization process. In some examples, the pressure shock wave treatment process may be a laser-based cavitation process. In some examples, the pressure shock wave treatment process may be an ultrasonic cavitation process.

In some examples, the treatment process may be a stimulation of vibrational modes in the graphite structure. In some examples, the stimulation of vibrational modes may be applying mechanical interactions to a lattice of the graphite structures. In some examples, the stimulation of vibrational modes may include providing the graphite structure in a fluid and transferring vibrational energy to the graphite structure through the fluid. In some examples, the stimulation of vibrational modes may include providing the graphite structure to a solid interface that imparts vibrational motion. In some examples, the stimulation of vibrational modes may include transferring vibrational energy to the graphite structure with electrical or electromagnetic radiation. In some examples, the stimulation of vibrational modes may include modifying a crystal lattice of the graphite structures to form hybrid atomic orbitals.

In some examples, the treatment process may be a laser-based process performed on the graphite structures. For instance, one or more lasers may be emitted onto the graphite structures to remove material from the graphite structures (e.g., through an ablation process) or to heat the graphite structures.

In some examples, the treatment process may be a chemical exfoliation process. In some examples, the chemical exfoliation process may expose the graphite structures to a reactive gas. In some examples, the chemical exfoliation process may expose the graphite structures to a basic solution. In some examples, exposure to the basic solution may include at least partially submerging the graphite structure in the basic solution. In some examples, exposure to the basic solution may include exposure of the graphite structure to a vapor from a basic solution. In some examples, exposure to the basic solution may include coating (e.g. spray-coating, spin coating, manual application of the basic solution using tools, etc.) the graphite structure with a basic solution. In some examples, the basic solution may comprise potassium hydroxide, sodium hydroxide, or ammonium hydroxide.

In some examples, the treatment process may expose the graphite structures to an electrochemical bath. In some examples, the treatment process may expose the graphite structures to a plasma, such as an oxidizing plasma. In some examples, the treatment process may include providing the graphite structures in a liquid and causing evaporation of the liquid.

In some examples, the treatment process may be a thermal treatment of the graphite structures.

At 506, the method 500 includes providing the treated graphite structure to a crystal growth system. The treated graphite structure may have an exposed graphite surface within the crystal growth system. Example crystal growth systems are described with reference to FIGS. 1-3.

At 508, the method 500 includes conducting a crystal growth process in the crystal growth system, such as a silicon carbide crystal growth sublimation system, containing the treated graphite structure. Silicon carbide crystalline material may be produced using seeded sublimation crystal growth processes. A seed material and a source material may be arranged in a reaction crucible which is then heated to a sublimation temperature of the source material. By controlled heating of the environment surrounding the reaction crucible, a thermal gradient is developed between the sublimating source material and the marginally cooler seed material. By means of the thermal gradient, source material in a vapor phase is transported onto the seed material where it is deposited to grow a solid bulk crystalline boule.

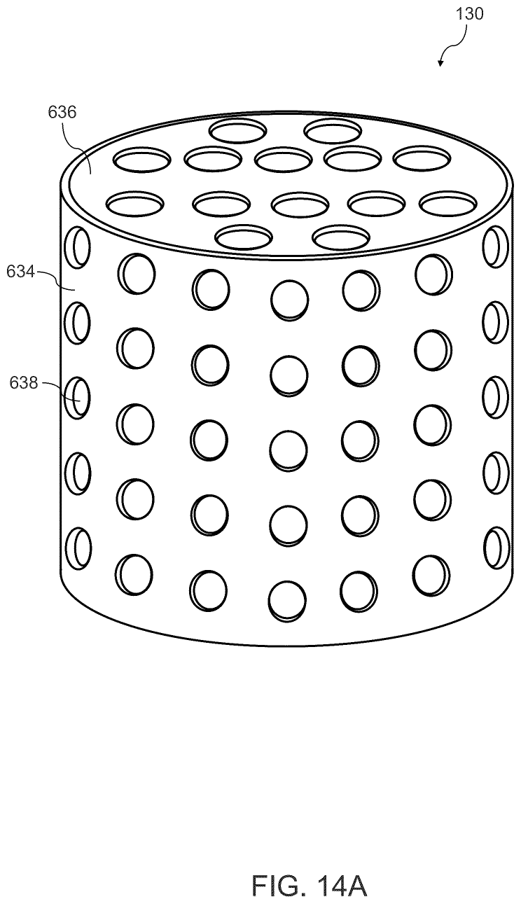

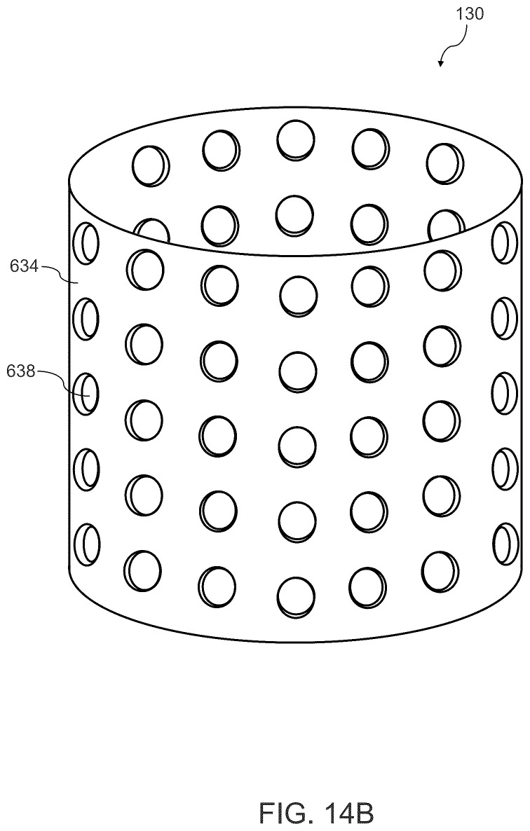

In some examples, the treated graphite structures according to examples of the present disclosure are source retention mechanisms used in crystal growth systems. Example embodiments of source retention mechanisms 130 are shown in FIG. 14A. in FIG. 14D, the source retention mechanism 130 contains cylindrical side walls 634, a cap 636, and channels 638 formed in the side walls 634 and the cap 636. As shown in FIG. 14A, the channels may all have the same or a similar diameter. In some embodiments, the diameters of the channels may be different and designed based on desired vapor flow paths and flowrates. For example, in some embodiments, the cap may have larger channels, or even one large central channel, relative to smaller or no peripheral channels.

The retention mechanism can be used to contain a source material (e.g., silicon carbide vapor source material. The channels 638 allow sublimated vapor to escape into the main chamber of the reaction crucible where they can reach the seed material or growing crystal. The channels may be designed/located to control the vapor flow within the crucible. For example, they can direct the vapor to specific parts of the seed material or growing crystal. In some embodiments, the channels in the side walls 634 may be omitted so that sublimated vapor can only exit through the channels in the cap 636. In some embodiments, the cap 636 may be omitted, as shown in FIG. 14D. In some embodiments, rather than, or in addition to, channels 638, the source walls and/or cap of the retention mechanism may be made from a highly porous material that the sublimated vapor can escape through. The source retention mechanism 130 may have different regions with different porosity.

As discussed, the retention mechanism 130 of FIGS. 14A and 14B may be graphite structures. The graphite structures may be treated according to examples of the present disclosure, for instance, to reduce particle erosion.

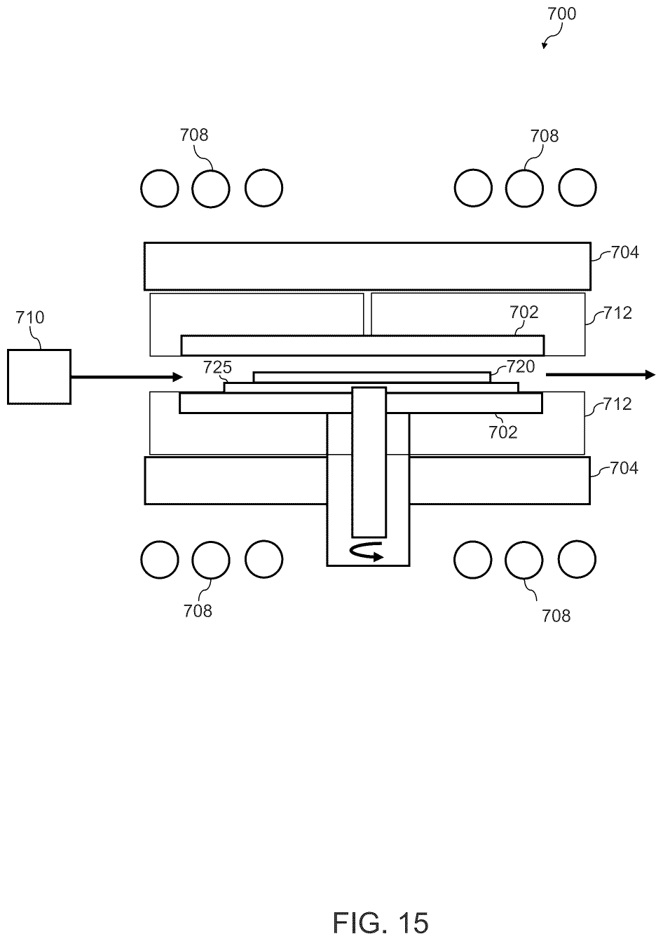

FIG. 15 depicts an example deposition system 700 (e.g., epitaxial reactor) that may include treated graphite structures according to example embodiments of the present disclosure. The deposition system 700 may be a horizontal, hot wall, flow through, CVD system as shown including a susceptor assembly 702, a quartz tube 704 defining a through passage 706, an electromagnetic frequency (EMF) generator 708 (for example, including a power supply and an RF coil surrounding the tube 704) and a process gas supply system 710. An insulative cover 712 may be provided about the susceptor assembly 702 in addition to or in place of the quartz tube 704 The deposition system 700 may be used to form a layer or film (e.g., epitaxial layer) on a workpiece 720 (e.g., a silicon carbide semiconductor wafer). In some examples, the deposition process using the deposition system 100 may occur at a process temperature in a range of about 900° C. to about 1700° C. While only a single workpiece 715 is shown in FIG. 15, the system 700 may be adapted to form films concurrently on multiple workpieces without deviating from the scope of the present disclosure.

The workpiece 720 may be on a workpiece holder 725. The workpiece holder 725, in some examples, may be coupled to a rotation shaft to provide rotation of the workpiece 720 during processing.

In some embodiments, the process gas supply system 710 may supply a process gas into and through the susceptor assembly 702 as discussed below. The EMF generator 708 inductively heats the susceptor assembly 702 to provide a hot zone in the susceptor assembly 702 where deposition reactions take place. The process gas continues through and out of the susceptor assembly 702 as an exhaust gas which may include remaining components of the process gas as well as reaction by-products, for example.

The susceptor assembly 702 and/or the insulative cover 712 may be, at least in part, a graphite structure. In some embodiments, the susceptor assembly 702 and/or the insulative cover 712 may be a treated graphite structure according to example embodiments of the present disclosure.

FIG. 15 depicts a hot wall deposition system for purposes of illustration and discussion. Those of ordinary skill in the art, using the disclosures provided herein, will understand that treated graphite structures according to examples of the present disclosure may be used with other deposition systems without deviating from the scope of the present disclosure, such as warm wall deposition systems, deposition systems having a showerhead, etc.

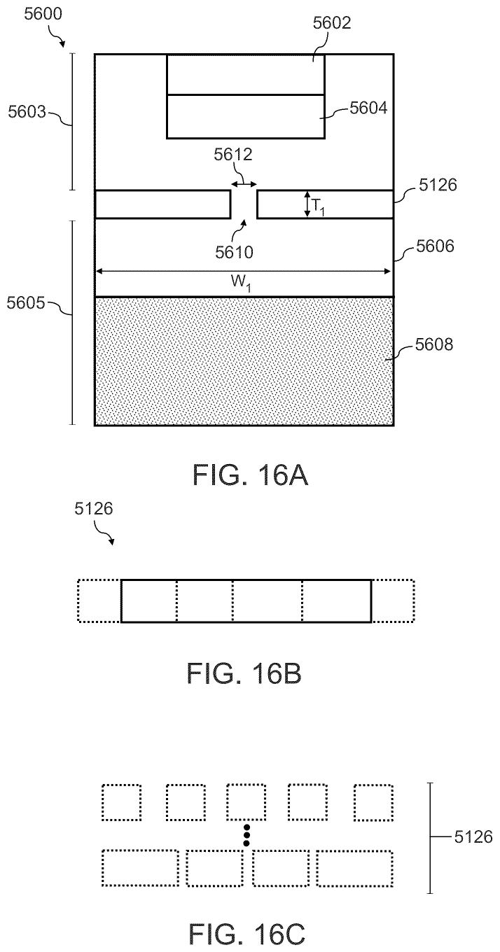

FIGS. 16A-23 depict example crystal growth systems that include a baffle that may be a treated graphite structure according to example embodiments of the present disclosure. FIG. 16A depicts a simplified view of a crystal growth system 5600 according to example aspects of the present disclosure. The crystal growth system 5600 includes the seed holder 5602 configured to hold the seed crystal 5604. The seed crystal 5604 may provide a growth surface for growth of the silicon carbide crystalline material in a crystal growth process. The crystal growth system 5600 includes the crucible 5606 defining a crystal growth chamber. The crystal growth system 5600 includes the source material 5608. The crystal growth system 5600 includes a baffle 5126 within the crystal growth chamber that is spaced apart from the source material 5608. In some embodiments, the baffle 5126 may extend between the inner walls of the crucible 5606, such that the crucible 5606 is bisected or divided into an upper portion 5603 and a lower portion 5605 by the baffle 5126. The upper portion 5603 and the lower portion 5605 may have the same or different volumes. In some examples, the baffle 5126 may be coupled to a side wall of the crucible 5606. In some examples, the baffle 5126 may not fully extend between the inner walls of the crucible 5606.

The baffle 5126 has a long dimension (e.g., width) W1 and a thickness T1. The thickness T1 is in a general direction of vapor transport through the baffle 5126. In some embodiments, the long dimension W1 is in a direction that is non-perpendicular to the growth surface of the seed crystal 5604.

FIG. 16B depicts a simplified view of baffle 5126 according to some aspects of the present disclosure. As shown in FIG. 16B, baffle 5126 may include apertures, and may extend to the side walls of the crucible, or may not extend to the sidewalls of the crucible.

FIG. 16C depicts a simplified view of baffle 5126 according to some aspects of the present disclosure. As shown in FIG. 16C, baffle 5126 may include multiple baffle structures, which may be spaced apart from one another or may be in contact with one another.

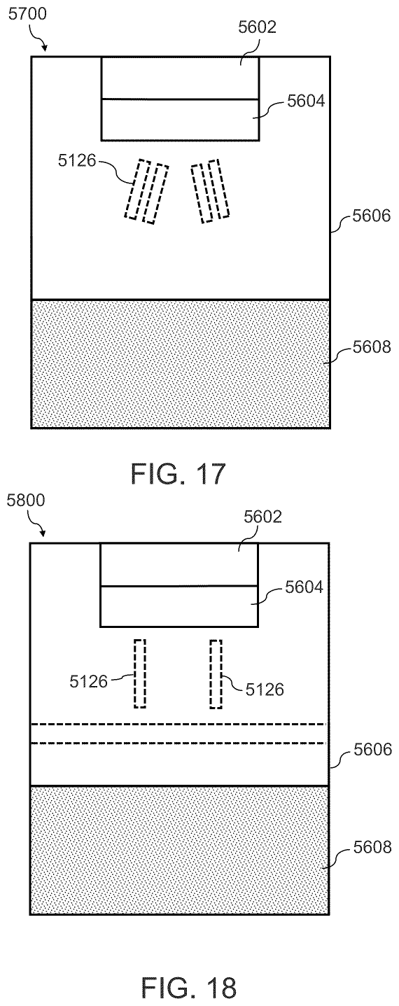

FIGS. 17, 18, 19, 20, 21, 22 and 23 depict simplified views of a baffle 5126 according to some aspects of the present disclosure in the context of crystal growth systems 5700, 5800, 5900, 6000, 6050, 6100, and 6200. As shown in FIG. 17, in some embodiments of the present disclosure, baffle 5126 may include one or more baffle plates, in any orientation relative to the seed holder 5602 or the source material 5608. As shown in FIG. 18, in some embodiments of the present disclosure, the baffle 5126 may include two or more baffle structures, whether of the same type or of differing types, and such baffle structures may be of differing orientations relative to each other.

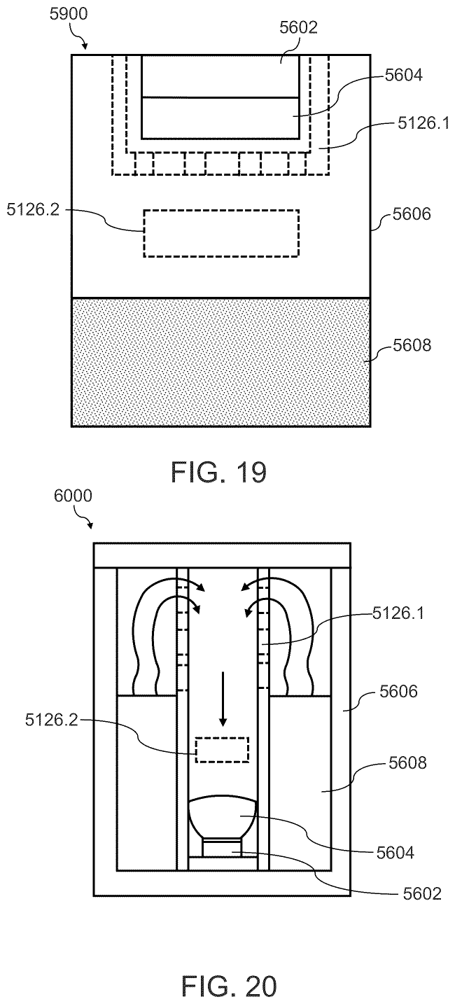

FIG. 19 depicts an example crystal growth system 5900 according to example embodiments of the present disclosure. In FIG. 19, the crystal growth system 5900 includes the baffle 5126.1, the seed holder 5602, the seed crystal 5604, the crucible 5606, and the source material 5608. The baffle 5126.1 may or may not include any apertures. The baffle 5126.1 may be porous graphite and may have a porosity of greater than about 70%. The baffle 5126 may be positioned such that the baffle 5126.1 extends around at least three sides of the seed crystal 5604, with the longest dimension located below the seed crystal 5604. The baffle 5126.1 may be referred to as a shell structure as it provides a shell around the seed crystal 5604. The baffle 5126 may be graphite, such as porous graphite. The baffle 5126.1 may include one or more apertures 5610 that assist in the transport of source vapor from the source material 5608 to the seed crystal 5604. The system 5900 may further include one or more second baffles 5126.2. The one or more second baffles 5126.2 may be arranged in the vapor transport path between the source material 5608 and the seed crystal 5604. The one or more second baffles 5126.2 may include any of the baffles disclosed in U.S. patent application Ser. No. 18/962,454 filed on Nov. 27, 2024, which is incorporated herein by reference.

FIG. 20 depicts an example crystal growth system 6000 according to example embodiments of the present disclosure. In FIG. 20, the crystal growth system 6000 includes a baffle 5126.1, a seed holder 5602, a seed crystal 5604, a crucible 5606, and the source material 5608. The baffle 5126.1 may include a tubular baffle structure. The baffle 5126.1 may or may not include apertures. The seed crystal 5604 may be within the tubular baffle 5126.1. The baffle 5126.1 may be graphite, such as porous graphite. The baffle 5126.1 may be porous graphite and may have a porosity of greater than about 70%. The baffle 5126.1 may include one or more apertures 5610 that assist in the transport of source vapor from the source material 5608 to the seed crystal 5604. The system 6000 may further include one or more second baffles 5126.2. The one or more second baffles 126.2 may be arranged in the vapor transport path between the source material 5608 and the seed crystal 5604. The one or more second baffles 5126.2 may include any of the baffles disclosed in U.S. patent application Ser. No. 18/962,454 filed on Nov. 27, 2024, which is incorporated herein by reference. The baffle 5126.1 and/or the baffle 5126.2 may serve to reduce graphite inclusions or other impurities resulting from gravitational forces pulling impurities toward the seed crystal 5604.

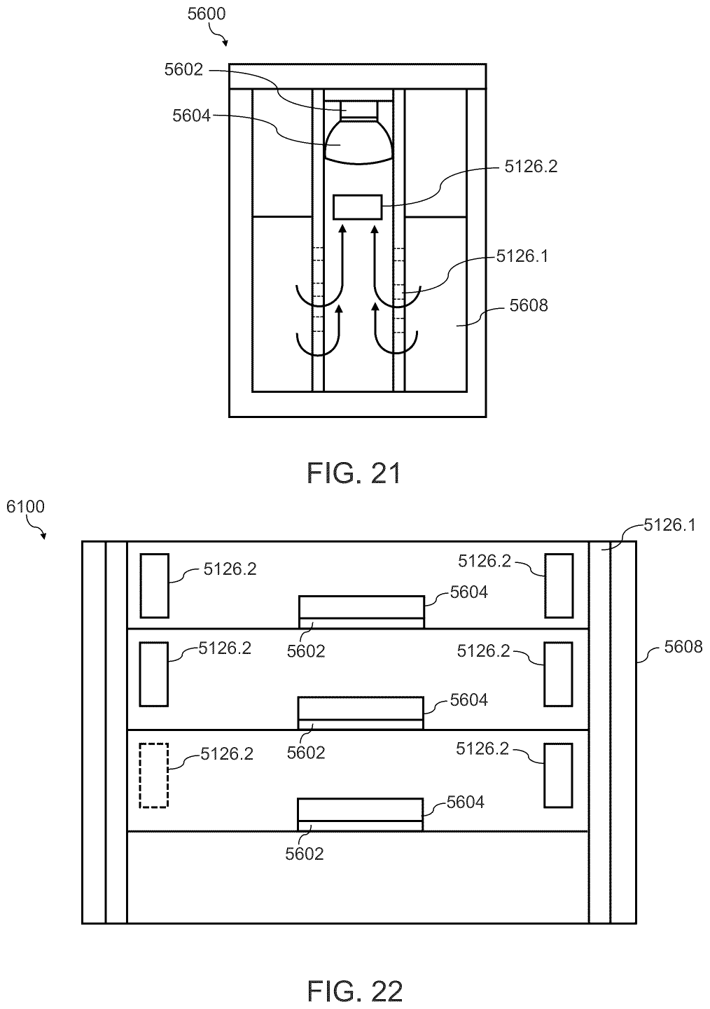

In FIG. 21, the crystal growth system 6050 includes the seed crystal 5604 at the top of the crucible 5606. Similar to FIG. 20, the baffle 5126.1 may include a tubular baffle structure. The seed crystal 5604 may be within the tubular baffle 5126.1. The baffle 5126.1 may be graphite, such as porous graphite. The baffle 5126.1 may be porous graphite and may have a porosity of greater than about 70%. The baffle 5126.1 may include one or more apertures 5610 that assist in the transport of source vapor from the source material 5608 to the seed crystal 5604. The system 6000 may further include one or more second baffles 5126.2. The one or more second baffles 5126.2 may be arranged in the vapor transport path between the source material 5608 and the seed crystal 5604. The one or more second baffles 5126.2 may include any of the baffles disclosed in U.S. patent application Ser. No. 18/962,454 filed on Nov. 27, 2024, which is incorporated herein by reference.

FIG. 22 depicts an example crystal growth system 6100 that may be used to grow a plurality of silicon carbide boules according to example embodiments of the present disclosure. In FIG. 22, the crystal growth system 6100 includes a plurality of seed holders 5602 and seed crystals 5604 arranged in different crystal growth chambers. A baffle 5126.1 may separate the seed crystals 5604 from a source material 5608. The baffle 5126.1 may include one or more apertures to assist with vapor transport from the source material 5608 to the seed crystals 5604. The system 6100 may further include one or more second baffles 5126.2. The one or more second baffles 5126.2 may be arranged in the vapor transport path between the source material 5608 and the seed crystal 5604. The one or more second baffles 5126.2 may include any of the baffles disclosed in U.S. patent application Ser. No. 18/962,454 filed on Nov. 27, 2024, which is incorporated herein by reference.

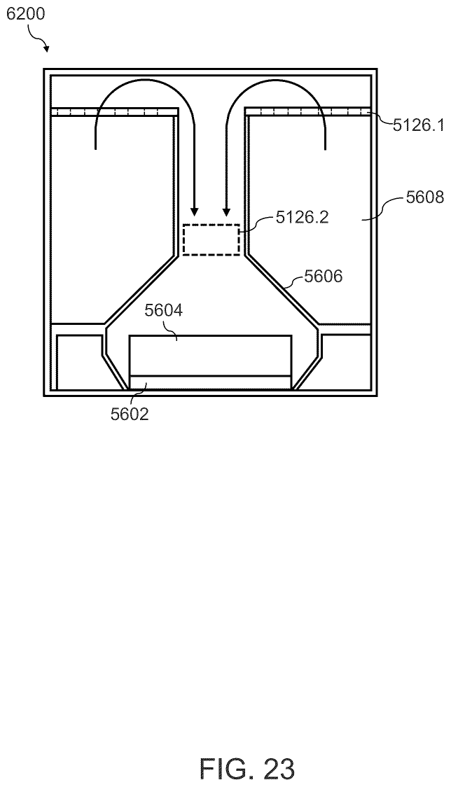

FIG. 23 depicts an example crystal growth system 6200 according to example embodiments of the present disclosure. In FIG. 23, the crystal growth system 6200 includes a seed holder 5602 and a seed crystal 5604 arranged within a crucible 5606. The crucible 5606 may have one or more angled sidewalls. The crystal growth system 6200 includes a source material 5608. The baffle 5126.1 may be on top of the source material 5608 and may separate the source material 5608 from the reaction chamber defined by the crucible 5606. As depicted in FIG. 23, the baffle 5126.1 may include one or more apertures to assist with vapor transport from the source material 5608 to the seed crystal 5604. The system 6100 may further include one or more second baffles 5126.2. The one or more second baffles 5126.2 may be arranged in the vapor transport path between the source material 5608 and the seed crystal 5604. The one or more second baffles 5126.2 may include any of the baffles disclosed in U.S. patent application Ser. No. 18/962,454 filed on Nov. 27, 2024, which is incorporated herein by reference.

In any of the simplified crystal growth systems with a baffle 5126 depicted in FIGS. 16A-23 or graphite structure 126 of FIGS. 1-3, the baffle may provide vapor transport of a silicon carbide source vapor through a first portion of the baffle at a first rate. In some embodiments, the silicon carbide vapor may be transported through a second portion of the baffle (e.g., including one or more apertures), at a second rate. The first rate may be different than the second rate. For example, the baffle may provide an avenue for source vapor to diffuse through the material of the baffle at a first rate, while source vapor is transported through an aperture unimpeded by the material of the baffle at a second rate.

In some embodiments, the baffle may be spaced apart from the seed holder and is not coupled to the seed holder. In some embodiments, the baffle may impede or otherwise alter heat transfer or thermal energy within the crystal growth chamber in a crystal growth process.

In some embodiments, the baffle may be, at least partially, made of graphite. In some embodiments, the baffle made at least partially of graphite may include a coating on at least a portion of the graphite. In some embodiments, the coating on the baffle made of graphite may be a pyrolytic coating. In some embodiments, the coating on the baffle made of graphite may be tantalum carbide. In some embodiments, the coating on the baffle may hinder particulate matter larger than the source vapor from reaching a seed crystal. The seed crystal may be a silicon carbide seed crystal.

In some examples, the graphite is porous graphite. For instance, the baffle may have a porosity in a range of about 50% to about 97%, such as about 75% to about 97%, such as about 80% to about 97%. Other suitable materials may be used without deviating from the scope of the present disclosure. For instance, the baffle may comprise a carbide material, such as vanadium carbide, tantalum carbide, silicon carbide. The carbide material may form a bulk of the baffle.

In some examples, at least a portion of the baffle includes uncoated graphite or exposed graphite. For instance, at least a portion of a surface of the baffle facing the seed crystal may be exposed or uncoated graphite. This will allow that baffle to serve as a secondary source to improve crystal growth during a PVT crystal growth process.

The seed crystal may be a silicon carbide seed crystal. In some embodiments, the baffle may be spaced apart from a seed holder and is not coupled to the seed holder. In some embodiments, the baffle may be spaced apart from a source material and is not coupled to the source material. The source material may be a silicon carbide vapor source material. In some embodiments, the baffle may be coupled to a side wall of a crucible. In some embodiments, the baffle, or an individual baffle plate in embodiments including a plurality of baffle plates or baffle structures, may have a thickness that is in a range of about 0.5 mm to about 25 mm, such as 2 mm to about 12 mm, such as about 2 mm to about 8 mm.

In some embodiments, the baffle can include single or multiple elements that perform one of more of the following: effecting/providing temperature gradient in a desired manner relative to the crystal growth surface, effecting/providing vapor pressure/flux/flow for/to/from the source material (e.g., silicon carbon source material, secondary source material, or dopant source relative to the crystal growth surface, side surface of the seed crystal and/or areas within the reactor susceptible to parasitic growth; and filtering graphite or other inclusions from the crystal. In some embodiments, different elements or portions of the baffle can provide different features, such as one element for filtering, another element acting as a secondary source (e.g., a graphite element that provides a carbon source and provides temperature gradient and vapor pressure/flux effects); and an element with apertures, pores, voids, cavities, indentations and/or protrusions to effect temperature gradient and/or vapor flow/pressure effects. One or more of the baffles 126 can be coated with a high temperature carbide, such as TaC or the like) while others are not. Portions or the entire baffle can be coated or not with a single, multiple and/or patterned coating(s), for instance, to achieve desired sublimation if acting as a secondary source, or to reduce sublimation if not intended to serve as a secondary source. Individual baffles or baffle elements can serve duplicate or different functions.

Example aspects of the present disclosure are set forth below. Any of the below features or examples may be used in combination with any of the embodiments or features provided in the present disclosure.

In an aspect, the present disclosure provides an example method for treating a graphite structure. The method includes implementing a treatment process to a graphite structure to alter one or more characteristics of the graphite structure to produce a treated graphite structure. The method includes providing the treated graphite structure to a crystal growth system or a deposition system. At least a portion of the treated graphite structure has an exposed graphite surface within the crystal growth system or the deposition system.

In some implementations of the example method, the treated graphite structure is a component part of the crystal growth system.

In some implementations of the example method, the treated graphite structure provides for a flow of a fluid through the treated graphite structure.

In some implementations of the example method, the treated graphite structure is at least a part of a source cap in the crystal growth system.

In some implementations of the example method, the one or more characteristics comprise a permeability characteristic associated with a flow of a fluid through the treated graphite structure.

In some implementations of the example method, the permeability characteristic includes a porosity, a pore size, a pore distribution, a gas permeability, or a particle erosion rate.

In some implementations of the example method, the one or more characteristics of the graphite structure comprise one or more of a purity, a coefficient of thermal expansion, a flexural strength, or a resistivity.

In some implementations of the example method, the crystal growth system is a silicon carbide crystal growth sublimation system.

In some implementations of the example method, the treated graphite structure has a reduced particle erosion rate associated with a flow of a fluid through the graphite structure relative to an untreated graphite structure.

In some implementations of the example method, the method further comprises conducting a crystal growth process in the crystal growth system.

In some implementations of the example method, the treated graphite structure reduces carbon inclusions within a growth crystal.

In some implementations of the example method, the treatment process alters a permeability of the treated graphite structure by about 1% to about 50%.

In some implementations of the example method, the treatment process modifies a specific surface area of the treated graphite structure by a factor of about 1.1 to about 1000.

In some implementations of the example method, the treated graphite structure does not include a coating on a surface of the graphite structure.

In some implementations of the example method, the treatment process is implemented as a pretreatment process prior to application of a coating.

In some implementations of the example method, the treatment process is implemented as a post-treatment process after application of a coating.

In some implementations of the example method, the treatment process includes exposing the graphite structure to a pressure shock wave treatment process.

In some implementations of the example method, the pressure shock wave treatment process includes a homogenization process.

In some implementations of the example method, the pressure shock wave treatment process includes a laser-based cavitation process.

In some implementations of the example method, the pressure shock wave treatment process includes an ultrasonic cavitation process.

In some implementations of the example method, the treatment process includes a stimulation of vibrational modes in the graphite structure.

In some implementations of the example method, the stimulation of vibrational modes includes applying mechanical interactions to a crystal lattice of the graphite structure.

In some implementations of the example method, the stimulation of vibrational modes includes providing the graphite structure in a fluid and transferring vibrational energy to the graphite structure through the fluid.

In some implementations of the example method, the stimulation of vibrational modes includes providing the graphite structure to a solid interface that imparts vibrational motion.

In some implementations of the example method, the stimulation of vibrational modes includes transferring vibrational energy to the graphite structure with electrical or electromagnetic radiation.

In some implementations of the example method, the stimulation of vibrational modes includes modifying a crystal lattice of the graphite structure to form hybrid atomic orbitals.

In some implementations of the example method, the treatment process includes performing a laser-based process of the graphite structure.

In some implementations of the example method, the treatment process includes a chemical exfoliation process.

In some implementations of the example method, the chemical exfoliation process includes exposing the graphite structure to a reactive gas.

In some implementations of the example method, the chemical exfoliation process includes exposing the graphite structure to a basic solution.

In some implementations of the example method, exposing the graphite structure to the basic solution includes at least partially submerging the graphite structure in the basic solution.

In some implementations of the example method, exposing the graphite structure to the basic solution includes a vapor from a basic solution.

In some implementations of the example method, exposing the graphite structure to the basic solution includes a coating of the graphite structure with the basic solution, wherein the coating includes spray-coating, spin coating, or manual application of the basic solution.

In some implementations of the example method, the basic solution includes potassium hydroxide, sodium hydroxide, or ammonium hydroxide.

In some implementations of the example method, the treatment process includes exposing the graphite structure to an electrochemical bath.

In some implementations of the example method, the treatment process includes exposure of the graphite structure to a plasma.

In some implementations of the example method, the plasma is an oxidizing plasma.

In some implementations of the example method, the treatment process includes providing the graphite structure in a liquid and causing evaporation of the liquid.

In some implementations of the example method, the treatment process includes a thermal treatment of the graphite structure.

In some implementations of the example method, the thermal treatment includes heating the graphite structure to a temperature in a range of about 50° C. to about 130° C. to polymerize infiltrated or adsorbed materials.

In some implementations of the example method, the thermal treatment includes heating the graphite structure to a temperature in a range of about 25° C. to about 80° C. to conduct a dry-cleaning process.

In some implementations of the example method, the thermal treatment includes heating the graphite structure to a temperature in a range of about 60° C. to about 180° C. to evaporate one or more solvents.

In some implementations of the example method, the thermal treatment includes heating the graphite structure to a temperature in a range of about 100° C. to about 300° C. to evaporate one or more higher molecular weight organics.

In some implementations of the example method, the thermal treatment includes heating the graphite structure to a temperature in a range of about 300° C. to about 2000° C. to oxidize, desorb chemisorbed matter, or sinter the graphite structure.

In some implementations of the example method, the thermal treatment includes heating the graphite structure to a temperature in a range of about 2000° C. to about 3000° C. to recrystallize the graphite structure.

In some implementations of the example method, the treatment process is a selective treatment process that modifies one or more characteristics of a first portion of the graphite structure and one or more characteristics of a second portion of the graphite structure remain unmodified.

In an aspect, the present disclosure provides an example method for treating a graphite structure. The method includes implementing a treatment process to a graphite structure to alter one or more permeability characteristics of the graphite structure to produce a treated graphite structure. The method includes providing the treated graphite structure to a crystal growth system or a deposition system. One or more permeability characteristics are associated with a flow of a fluid through the treated graphite structure.

In some implementations of the example method, the treated graphite structure is a component part of the crystal growth system.

In some implementations of the example method, the treated graphite structure provides for flow of the fluid through the treated graphite structure.

In some implementations of the example method, the treated graphite structure is at least a part of a source cap in the crystal growth system.

In some implementations of the example method, the permeability characteristic includes a porosity, a pore size, a pore distribution, a gas permeability, or a particle erosion rate.

In some implementations of the example method, the treated graphite structure includes one or more characteristics including one or more of a purity, a coefficient of thermal expansion, a flexural strength, or a resistivity.

In some implementations of the example method, the crystal growth system is a silicon carbide crystal growth sublimation system.

In some implementations of the example method, the method further comprises conducting a crystal growth process in the crystal growth system.

In some implementations of the example method, the treated graphite structure reduces carbon inclusions within a growth crystal.

In some implementations of the example method, the treatment process alters a permeability of the treated graphite structure by about 1% to about 50%.

In some implementations of the example method, the treated graphite structure contains less than 10 ppm of impurities by weight.

In some implementations of the example method, at least a portion of the treated graphite structure has an exposed graphite surface within the crystal growth system.

In some implementations of the example method, the treatment process includes exposing the graphite structure to a pressure shock wave treatment process.

In some implementations of the example method, the pressure shock wave treatment process includes a homogenization process.

In some implementations of the example method, the pressure shock wave treatment process includes a laser-based cavitation process.

In some implementations of the example method, the pressure shock wave treatment process includes an ultrasonic cavitation process.

In some implementations of the example method, the treatment process includes a stimulation of vibrational modes in the graphite structure.

In some implementations of the example method, the stimulation of vibrational modes includes applying mechanical interactions to a crystal lattice of the graphite structure.

In some implementations of the example method, the stimulation of vibrational modes includes providing the graphite structure in a fluid and transferring vibrational energy to the graphite structure through the fluid.

In some implementations of the example method, the stimulation of vibrational modes includes providing the graphite structure to a solid interface that imparts vibrational motion.

In some implementations of the example method, the stimulation of vibrational modes includes transferring vibrational energy to the graphite structure with electrical or electromagnetic radiation.

In some implementations of the example method, the stimulation of vibrational modes includes modifying a crystal lattice of the graphite structure to form hybrid atomic orbitals.

In some implementations of the example method, the treatment process includes performing a laser-based process of the graphite structure.

In some implementations of the example method, the treatment process includes a chemical exfoliation process.

In some implementations of the example method, the chemical exfoliation process includes exposing the graphite structure to a reactive gas.

In some implementations of the example method, the chemical exfoliation process includes exposing the graphite structure to a basic solution.

In some implementations of the example method, exposing the graphite structure to the basic solution includes at least partially submerging the graphite structure in the basic solution.

In some implementations of the example method, exposing the graphite structure the basic solution includes a vapor from a basic solution.

In some implementations of the example method, exposing the graphite structure to the basic solution includes a coating of the graphite structure with the basic solution, wherein the coating includes spray-coating, spin coating, or manual application of the basic solution.

In some implementations of the example method, the basic solution includes potassium hydroxide, sodium hydroxide, or ammonium hydroxide.

In some implementations of the example method, the treatment process includes exposing the graphite structure to an electrochemical bath.

In some implementations of the example method, the treatment process includes exposure of the graphite structure to a plasma.

In some implementations of the example method, the plasma is an oxidizing plasma.

In some implementations of the example method, the treatment process includes providing the graphite structure in a liquid and causing evaporation of the liquid.

In some implementations of the example method, the treatment process includes thermal treatment of the graphite structure.

In some implementations of the example method, the thermal treatment includes heating the graphite structure to a temperature in a range of about 50° C. to about 130° C. to polymerize infiltrated or adsorbed materials.

In some implementations of the example method, the thermal treatment includes heating the graphite structure to a temperature in a range of about 25° C. to about 80° C. to conduct a dry-cleaning process.

In some implementations of the example method, the thermal treatment includes heating the graphite structure to a temperature in a range of about 60° C. to about 180° C. to evaporate one or more solvents.

In some implementations of the example method, the thermal treatment includes heating the graphite structure to a temperature in a range of about 100° C. to about 300° C. to evaporate one or more higher molecular weight organics.

In some implementations of the example method, the thermal treatment includes heating the graphite structure to a temperature in a range of about 300° C. to about 2000° C. to oxidize, desorb chemisorbed matter, or sinter the graphite structure.

In some implementations of the example method, the thermal treatment includes heating the graphite structure to a temperature in a range of about 2000° C. to about 3000° C. to recrystallize the graphite structure.

In some implementations of the example method, the treatment process is implemented as a pretreatment process prior to application of a coating.

In some implementations of the example method, the treatment process is implemented as a post-treatment process after application of a coating.

In some implementations of the example method, the treatment process is a selective treatment process that modifies one or more characteristics of a first portion of the graphite structure and one or more characteristics of a second portion of the graphite structure remain unmodified.

In an aspect, the present disclosure provides an example crystal growth system. The crystal growth system includes a crucible. The crystal growth system includes a seed holder. The crystal growth system includes a source material within the crucible. The crystal growth system includes a treated graphite structure. The treated graphite structure accommodates a flow of a fluid through the treated graphite structure. The treated graphite structure has an exposed graphite surface in the crucible.

In some implementations of the example crystal growth system, the treated graphite structure is at least a part of a source cap in the crystal growth system.

In some implementations of the example crystal growth system, the treated graphite structure contains less than 10 ppm of impurities by weight.

In some implementations of the example crystal growth system, the crystal growth system is a sublimation system.

In some implementations of the example crystal growth system, the treated graphite structure.

In some implementations of the example crystal growth system, the treated graphite structure has a particle erosion rate that is less than a particle erosion rate of an untreated graphite structure.

In an aspect, the present disclosure provides an example system. The system includes a workpiece holder operable to hold a graphite structure for a crystal growth system. The system includes a treatment platform. The system includes a controller configured to control the treatment platform to implement a treatment process on the graphite structure to alter one or more characteristics of the graphite structure to produce a treated graphite structure.

In some implementations of the example system, the one or more characteristics comprise a permeability characteristic associated with a flow of a fluid through the treated graphite structure.

In some implementations of the example system, the permeability characteristic includes a porosity, a pore size, a pore distribution, a gas permeability, or a particle erosion rate.

In some implementations of the example system, the treated graphite structure provides for a flow of a fluid through the treated graphite structure.

In some implementations of the example system, the treated graphite structure has a reduced particle erosion rate associated with a flow of a fluid through the graphite structure relative to an untreated graphite structure.

In some implementations of the example system, the one or more characteristics comprise a purity, a coefficient of thermal expansion, a flexural strength, or a resistivity.

In some implementations of the example system, the treatment process alters a permeability of the treated graphite structure by about 1% to about 50%.

In some implementations of the example system, the treated graphite structure contains less than 10 ppm of impurities by weight.

In some implementations of the example system, the treatment process includes exposing the graphite structure to a pressure shock wave treatment process.

In some implementations of the example system, the pressure shock wave treatment process includes a homogenization process.

In some implementations of the example system, the pressure shock wave treatment process includes a laser-based cavitation process.

In some implementations of the example system, the pressure shock wave treatment process includes an ultrasonic cavitation process.

In some implementations of the example system, the treatment process includes a stimulation of one or more vibrational modes in the graphite structure.

In some implementations of the example system, the stimulation of one or more vibrational modes includes applying mechanical interactions to a crystal lattice of the graphite structure.

In some implementations of the example system, the stimulation of vibrational modes includes providing the graphite structure in a fluid and transferring vibrational energy to the graphite structure through the fluid.

In some implementations of the example system, the stimulation of vibrational modes includes providing the graphite structure to a solid interface that imparts vibrational motion.

In some implementations of the example system, the stimulation of vibrational modes includes transferring vibrational energy to the graphite structure with electrical or electromagnetic radiation.

In some implementations of the example system, the stimulation of vibrational modes includes modifying a crystal lattice of the graphite structure to form hybrid atomic orbitals.

In some implementations of the example system, the treatment process includes performing a laser-based process on the graphite structure.

In some implementations of the example system, the treatment process includes a chemical exfoliation process.

In some implementations of the example system, the chemical exfoliation process includes exposing the graphite structure to a reactive gas.

In some implementations of the example system, the chemical exfoliation process includes an exposure of the graphite structure to a basic solution.

In some implementations of the example system, exposing the graphite structure to the basic solution includes at least partially submerging the graphite structure in the basic solution.

In some implementations of the example system, exposing the graphite structure the basic solution includes a vapor from a basic solution.

In some implementations of the example system, exposing the graphite structure to the basic solution includes coating of the graphite structure with the basic solution, wherein the coating includes spray-coating, spin coating, or manual application of the basic solution.

In some implementations of the example system, the basic solution includes potassium hydroxide, sodium hydroxide, or ammonium hydroxide.

In some implementations of the example system, the treatment process includes exposing the graphite structure to an electrochemical bath.

In some implementations of the example system, the treatment process includes exposure of the graphite structure to a plasma.

In some implementations of the example system, the plasma is an oxidizing plasma.

In some implementations of the example system, the treatment process includes providing the graphite structure in a liquid and causing evaporation of the liquid.

In some implementations of the example system, the treatment process includes thermal treatment of the graphite structure.

In some implementations of the example system, the thermal treatment includes heating the graphite structure to a temperature in a range of about 50° C. to about 130° C. to polymerize infiltrated or adsorbed materials.

In some implementations of the example system, the thermal treatment includes heating the graphite structure to a temperature in a range of about 25° C. to about 80° C. to conduct a dry-cleaning process.

In some implementations of the example system, the thermal treatment includes heating the graphite structure to a temperature in a range of about 60° C. to about 180° C. to evaporate solvents, such as organic solvents, water, or alcohols.

In some implementations of the example system, the thermal treatment includes heating the graphite structures to a temperature in a range of about 100° C. to about 300° C. to evaporate higher molecular weight organics.

In some implementations of the example system, the thermal treatment includes heating the graphite structures to a temperature in a range of about 2000° C. to about 3000° C. to oxidize, desorb chemisorbed matter, or sinter the graphite structure.

In some implementations of the example system, the treatment process is implemented as a pretreatment process prior to application of a coating.

In some implementations of the example system, the treatment process is implemented as a post-treatment process after application of a coating.

In some implementations of the example system, the treatment process is a selective treatment process that modifies one or more characteristics of a first portion of the graphite structure and one or more characteristics of a second portion of the graphite structure remain unmodified.

While the present subject matter has been described in detail with respect to specific example embodiments thereof, it will be appreciated that those skilled in the art, upon attaining an understanding of the foregoing can readily produce alterations to, variations of, and equivalents to such embodiments. Accordingly, the scope of the present disclosure is by way of example rather than by way of limitation, and the subject disclosure does not preclude inclusion of such modifications, variations and/or additions to the present subject matter as would be readily apparent to one of ordinary skill in the art.

What is claimed is:

1. A method for treating a graphite structure, comprising:
implementing a treatment process to a graphite structure to alter one or more characteristics of the graphite structure to produce a treated graphite structure; and
providing the treated graphite structure to a crystal growth system or a deposition system, wherein at least a portion of the treated graphite structure has an exposed graphite surface within the crystal growth system or the deposition system.

2. The method of claim 1, wherein the treated graphite structure is a component part of the crystal growth system.

3. The method of claim 1, wherein the one or more characteristics comprise a permeability characteristic associated with a flow of a fluid through the treated graphite structure.

4. The method of claim 1, wherein the one or more characteristics of the graphite structure comprise one or more of a purity, a coefficient of thermal expansion, a flexural strength, or a resistivity.

5. The method of claim 1, wherein the crystal growth system is a silicon carbide crystal growth sublimation system.

6. The method of claim 1, wherein the treated graphite structure has a reduced particle erosion rate associated with a flow of a fluid through the graphite structure relative to an untreated graphite structure.

7. The method of claim 1, further comprising conducting a crystal growth process in the crystal growth system.

8. The method of claim 1, wherein the treated graphite structure reduces carbon inclusions within a growth crystal.

9. The method of claim 1, wherein the treatment process alters a permeability of the treated graphite structure by about 1% to about 50%.

10. The method of claim 1, wherein the treatment process modifies a specific surface area of the treated graphite structure by a factor of about 1.1 to about 1000.

11. The method of claim 1, wherein the treated graphite structure does not include a coating on a surface of the graphite structure.

12. The method of claim 1, wherein the treatment process is implemented as a pretreatment process prior to application of a coating.

13. The method of claim 1, wherein the treatment process is implemented as a post-treatment process after application of a coating.

14. The method of claim 1, wherein the treatment process comprises exposing the graphite structure to a pressure shock wave treatment process.

15. The method of claim 1, wherein the treatment process comprises a stimulation of vibrational modes in the graphite structure.

16. The method of claim 1, wherein the treatment process comprises performing a laser-based process of the graphite structure.

17. The method of claim 1, wherein the treatment process comprises a chemical exfoliation process.

18. The method of claim 1, wherein the treatment process comprises providing the graphite structure in a liquid and causing evaporation of the liquid.

19. The method of claim 1, wherein the treatment process comprises a thermal treatment of the graphite structure.

20. A method for treating a graphite structure, comprising:
implementing a treatment process to a graphite structure to alter one or more permeability characteristics of the graphite structure to produce a treated graphite structure;
providing the treated graphite structure to a crystal growth system or a deposition system; and
wherein the one or more permeability characteristics are associated with a flow of a fluid through the treated graphite structure.
